(19) United States
(12) Patent Application Publication
(10) Pub. No.: US 2023/0299015 A1
(43) Pub. Date: Sep. 21, 2023

(54) SEMICONDUCTOR MEMORY DEVICE

(71) Applicant: Kioxia Corporation, Tokyo (JP)

(72) Inventor: Hiroshi MATSUMOTO, Yokkaichi (JP)

(73) Assignee: Kioxia Corporation, Tokyo (JP)

(21) Appl. No.: 17/929,437

(22) Filed: Sep. 2, 2022

(30) Foreign Application Priority Data
Mar. 16, 2022 (JP) 2022-041176

(51) Int. Cl. H01L 23/00; H01L 23/535; H01L 27/11556; H01L 27/11582

(52) U.S. Cl. CPC H01L 23/562; H01L 23/535; H01L 27/11556; H01L 27/11582

(57) ABSTRACT

A substrate includes a first region and a second region around the first region. A layer stack is above the substrate in the first region in a first direction. A first conductor is on the substrate in the second region and extends in the first direction. A second conductor is on the first conductor and extends in a direction approaching the second region from the first region. A third conductor is on the second conductor and extends in the first direction, includes an upper surface reaching a height of an upper surface of the layer stack. The third conductor is positioned farther from the first region than the first conductor. The third conductor is not opposed to the first conductor in the first direction. A set of the first conductor, the second conductor, and the third conductor surrounds the first region.

### CROSS-REFERENCE TO RELATED APPLICATIONS

This application is based upon and claims the benefit of priority from Japanese Patent Application No. 2022-041176, filed Mar. 16, 2022, the entire contents of which are incorporated herein by reference.

### FIELD

Embodiments described herein relate generally to a semiconductor memory device.

### BACKGROUND

A NAND flash memory capable of storing data in a non-volatile manner is known.

### BRIEF DESCRIPTION OF THE DRAWINGS

FIG. 1 is a block diagram showing a configuration example of a semiconductor memory device 1 according to a first embodiment.

FIG. 2 is a circuit diagram showing an example of a circuit configuration of a memory cell array included in the semiconductor memory device 1 according to the first embodiment.

FIG. 3 is a planar view showing an example of a planar layout of the semiconductor memory device 1 according to the first embodiment.

FIG. 4 is a planar view showing an example of a planar layout of the memory cell array included in the semiconductor memory device 1 according to the first embodiment.

FIG. 5 is a cross-sectional view taken along line V-V of FIG. 4, showing an example of a cross-sectional structure of the memory cell array included in the semiconductor memory device 1 according to the first embodiment.

FIG. 6 is a cross-sectional view taken along line VI-VI of FIG. 5, showing an example of a cross-sectional structure of a memory pillar MP in the semiconductor memory device 1 according to the first embodiment.

FIG. 7 is a planar view showing an example of a planar layout of the semiconductor memory device 1 according to the first embodiment.

FIG. 8 is a planar view showing an example of a planar layout of the semiconductor memory device 1 according to the first embodiment.

FIG. 9 is a cross-sectional view taken along line IX-IX of FIGS. 7 and 8, showing an example of a cross-sectional structure of the semiconductor memory device 1 according to the first embodiment.

FIG. 10 shows an example of a planar layout of the semiconductor memory device 1 during manufacturing according to the first embodiment.

FIG. 11 shows an example of a planar layout of the semiconductor memory device 1 during manufacturing according to the first embodiment.

FIG. 12 shows an example of a cross-sectional structure of the semiconductor memory device 1 during manufacturing according to the first embodiment.

FIG. 13 shows an example of a cross-sectional structure of a semiconductor memory device 1r according to a comparative example of the first embodiment.

FIG. 14 shows an example of a cross-sectional structure of the semiconductor memory device 1 according to the first embodiment.

FIG. 15 shows an example of a cross-sectional structure of the semiconductor memory device 1 according to a first modification of the first embodiment.

FIG. 16 shows an example of a planar layout of the semiconductor memory device 1 according to a second modification of the first embodiment.

FIG. 17 is a cross-sectional view taken along line XVII-XVII of FIG. 16, showing an example of a cross-sectional structure of the semiconductor memory device 1 according to the second modification of the first embodiment.

FIG. 18 shows an example of a cross-sectional structure of a semiconductor memory device 1b according to a second embodiment.

FIG. 19 shows an example of a cross-sectional structure of the semiconductor memory device 1b during manufacturing according to the second embodiment.

FIG. 20 shows an example of a cross-sectional structure of the semiconductor memory device 1b during manufacturing according to a modification of the second embodiment.

FIG. 21 shows an example of a cross-sectional structure of the semiconductor memory device 1b during manufacturing according to a modification of the second embodiment.

### DETAILED DESCRIPTION

A semiconductor memory device according to an embodiment includes a substrate, a layer stack, a first conductor, a second conductor, and a third conductor. The substrate includes a first region and a second region that surrounds the first region as viewed from above. The layer stack is provided above the substrate in the first region as viewed in a first direction. The first conductor is provided on the substrate in the second region and extends in the first direction. The second conductor is provided on the first conductor and extends in a direction approaching the second region from the first region. The third conductor is provided on the second conductor and extends in the first direction, an upper surface of the third conductor reaching at least a height of an upper surface of the layer stack. The third conductor is positioned farther from the first region than the first conductor. The third conductor is not opposed to the first conductor in the first direction. A set of the first conductor, the second conductor, and the third conductor surrounds the first region as viewed from above.

Hereinafter, embodiments will be described with reference to the accompanying drawings. In the following description, components with substantially the same functionalities and configurations will be referred to with the same reference symbols, and repeated descriptions may be omitted. In order to distinguish components with substantially the same functionalities and configurations from each other, an additional numeral or letter may be added to the end of each reference numeral.

The figures are schematic, and the relation between the thickness and the area of a plane of a layer and the ratio of thicknesses of layers may differ from those in actuality. Accordingly, the concrete thicknesses, dimensions, etc. may be determined in view of the description to be given below. The figures may include components which differ in relations and/or ratios of dimensions in different figures. The entire description of a particular embodiment also applies to other embodiments unless explicitly mentioned otherwise or obviously excluded. Each embodiment illustrates a device and a method for materializing the technical idea of that embodiment, and the technical idea of each embodiment does not limit the quality of the material, shape, structure, arrangement of components, etc. to those that will be described below.

The expressions “approximately identical”, “substantially identical”, and “substantially uniform” as used herein refer to being intended to be the same, but not completely identical, allowing for errors due to limitations in manufacturing technology and/or measuring technology.

### <1> First Embodiment

### <1-1> Configuration (Structure)

Hereinafter, a description will be given of a semiconductor memory device 1 according to an embodiment.

### <1-1-1> Configuration of Semiconductor Memory Device 1

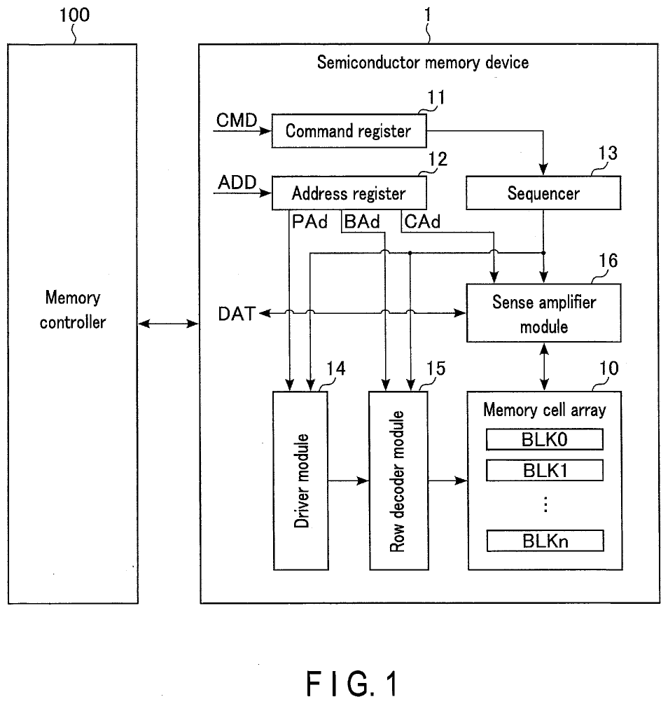

FIG. 1 shows a configuration example of a semiconductor memory device 1 according to a first embodiment. The semiconductor memory device 1 is a NAND-type flash memory capable of storing data in a non-volatile manner. The semiconductor memory device 1 is controlled by an external memory controller 100.

As shown in FIG. 1, the semiconductor memory device 1 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (where n is an integer equal to or greater than 1). Each block BLK includes a set of memory cell transistors MT (not illustrated) capable of storing data in a non-volatile manner, and is used as, for example, a unit of data erasure. A plurality of source lines SL, a plurality of word lines WL, a plurality of bit lines BL, etc. (not illustrated) are coupled to the memory cell array 10. Each memory cell transistor MT is associated with, for example, a single bit line BL and a single word line WL. A detailed configuration of the memory cell array 10 will be described later.

The command register 11 holds a command CMD received by the semiconductor memory device 1 from the memory controller 100. The command CMD includes, for example, an order to cause the sequencer 13 to perform a read operation, a write operation, an erase operation, etc.

The address register 12 holds address information ADD received by the semiconductor memory device 1 from the memory controller 100. The address information ADD includes, for example, a block address BAd, a page address PAd, and a column address CAd. The block address BAd, the page address PAd, and the column address CAd are used for selection of, for example, a block BLK, a word line WL, and a bit line BL, respectively.

The sequencer 13 controls the entire operation of the semiconductor memory device 1. For example, the sequencer 13 controls, based on the command CMD held in the command register 11, the driver module 14, the row decoder module 15, the sense amplifier module 16, etc., and performs a read operation, a write operation, an erase operation, etc.

The driver module 14 generates voltages used in a read operation, a write operation, an erase operation, etc., and supplies the generated voltages to the row decoder module 15. The driver module 14 applies the generated voltages to a signal line corresponding to the selected word line WL based on, for example, the page address PAd held in the address register 12.

The row decoder module 15 selects a single block BLK in the memory cell array 10 based on the block address BAd held in the address register 12. Subsequently, the row decoder module 15 transfers, to a selected word line WL in the selected block BLK, a voltage applied to a signal line coupled to the selected word line WL, for example.

In a write operation, the sense amplifier module 16 applies, to each bit line BL, a voltage that is determined according to write data DAT received from the memory controller 100. Also, in a read operation, the sense amplifier module 16 determines data stored in the memory cell transistor MT based on a voltage of the bit line BL, and transfers results of the determination to the memory controller 100 as read data DAT.

The semiconductor memory device 1 and the memory controller 100 described above may configure, in combination, a single semiconductor device. Examples of such a semiconductor device include a memory card such as an SD™ card and a solid-state drive (SSD).

### <1-1-2> Circuit Configuration of Memory Cell Array 10

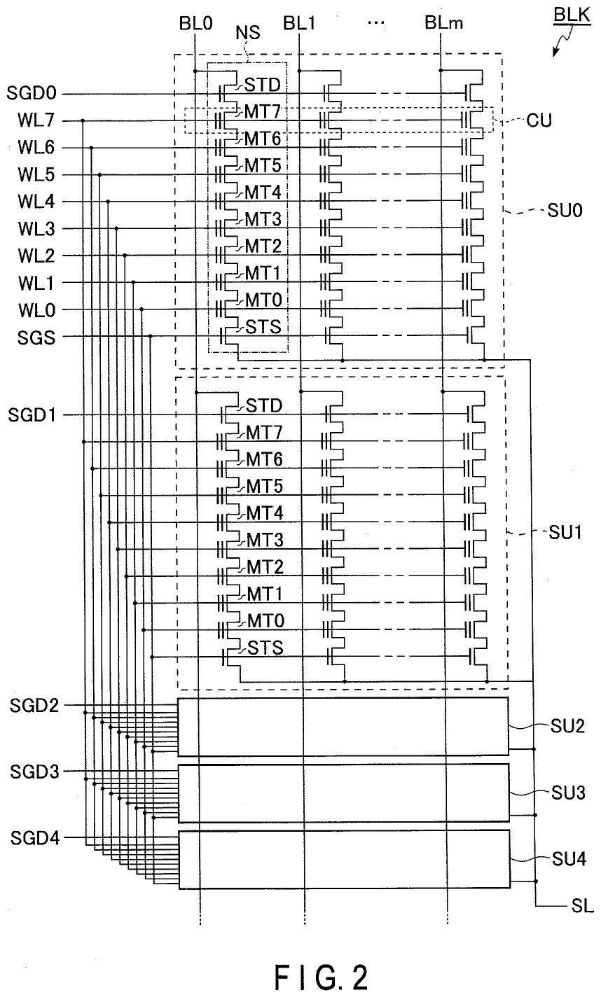

FIG. 2 is a circuit diagram showing an example of a circuit configuration of the memory cell array 10 included in the semiconductor memory device 1 according to the first embodiment. In FIG. 2, one of a plurality of blocks BLK included in the memory cell array 10 is extracted. All the other blocks BLK are configured of, for example, the components and couplings shown in FIG. 2. The number of blocks BLK in the memory cell array 10 and the number of string units SU in a single block BLK may be set to a given number. In the description that follows, a case is assumed where a single block BLK includes five string units SU0 to SU4.

Each string unit SU is a set of NAND strings NS respectively associated with bit lines BL0 to BLm (where m is an integer equal to or greater than 1). Each NAND string NS includes a plurality of memory cell transistors, for example, memory cell transistors MT0 to MT7, and select transistors STD and STS. In the description that follows, a case is assumed where each NAND string NS includes eight memory cell transistors MT0 to MT7.

Each memory cell transistor MT includes a control gate and a charge storage layer, and holds data in a non-volatile manner. Each of the select transistors STD and STS is used for selection of a string unit SU in various operations.

In each NAND string NS, the memory cell transistors MT0 to MT7 are coupled in series. A drain of the select transistor STD is coupled to a bit line BL associated therewith. A source of the select transistor STD is coupled to one end of the series of the memory cell transistors MT0 to MT7. The other end of the series of the memory cell transistors MT0 to MT7 is coupled to a drain of the select transistor STS. A source of the select transistor STS is coupled to a source line SL.

Control gates of the memory cell transistors MT0 to MT7 in the same block BLK are respectively coupled to the word lines WL0 to WL7. Gates of select transistors STD in the string units SU0 to SU4 are respectively coupled to the select gate lines SGD0 to SGD4. Gates of the select transistors STS are coupled to a select gate line SGS.

A column address is assigned to each of the bit lines BL0 to BLm. Each bit line BL is shared among a plurality of NAND strings NS of the respective blocks BLK. Each of the word lines WL0 to WL7 is provided for each block BLK. The source line SL is, for example, shared among a plurality of blocks BLK.

A set of memory cell transistors MT coupled to a common word line WL in a single string unit SU is referred to as, for example, a “cell unit CU”. The storage capacity of a cell unit CU including memory cell transistors MT that each stores, for example, 1-bit data is defined as “1-page data”. The cell unit CU may have a storage capacity of two or more pages of data according to the number of bits of data stored in the memory cell transistors MT.

The circuit configuration of the memory cell array 10 included in the semiconductor memory device 1 according to the first embodiment is not limited to the above-described configuration. For example, the number of memory cell transistors MT and the select transistors STD and STS included in each NAND string NS may be set to a given number.

### <1-1-3> Planar Structure of Memory Cell Array 10

Hereinafter, an example of a structure of the memory cell array 10 included in the semiconductor memory device 1 according to the first embodiment will be described. In the description that follows, an orthogonal coordinate system including an X axis, a Y axis, and a Z axis will be used. In the description that follows, the term “low” and its derivative and relevant terms refer to a position at a smaller coordinate on the Z axis, and the term “up” and its derivative and relevant terms refer to a position at a larger coordinate on the Z axis. In planar views, hatching is suitably applied for improved visibility. The hatching applied in the planar views does not necessarily relate to the material or characteristics of the hatched components. In the cross-sectional views, components such as insulating layers (interlayer insulating films), interconnects, contacts, etc. are suitably omitted for improved visibility.

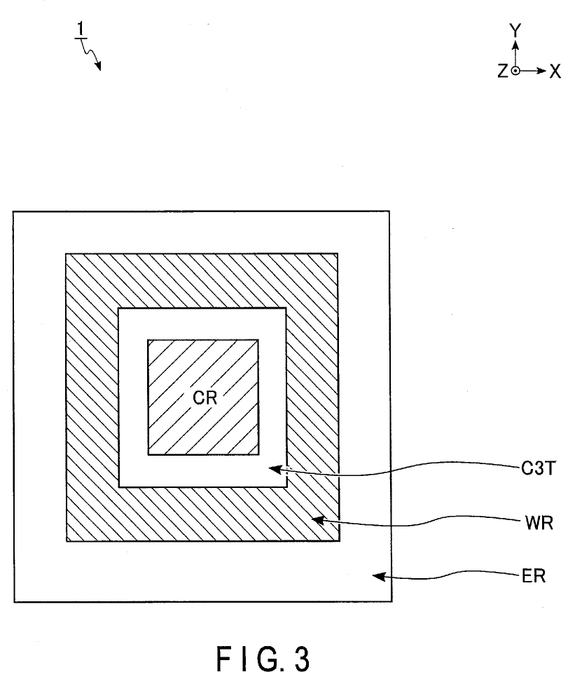

FIG. 3 is a planar view showing an example of a planar layout of the semiconductor memory device 1 according to the first embodiment. As shown in FIG. 3, the semiconductor memory device 1 in a planar layout is divided into, for example, a core region CR, a wall region WR, a contact region. C3T, and an end region ER.

The core region CR is, for example, a rectangular region provided at a central part of a semiconductor substrate 20. In the core region CR, the memory cell array 10 is arranged. The core region CR may be arranged in a given region in a given shape. If the semiconductor memory device 1 includes a plurality of memory cell arrays 10, the semiconductor memory device 1 may include a plurality of core regions CR.

The wall region WR is a rectangular toroidal region provided to surround the outer periphery of the core region CR. In the wall region WR, sealing members ESn and ESp, to be described later, are arranged. If a plurality of core regions CR are provided on the semiconductor substrate 20, the wall region WR may be provided so as to collectively surround the core regions CR, or may be provided for each core region CR. In the region surrounded by the wall region WR, peripheral circuitry such as the row decoder module 15 and the sense amplifier module 16 are arranged. The peripheral circuitry includes a portion that overlaps the memory cell array 10.

The contact region C3T is a region between the wall region WR and the core region CR. In the contact region C3T, a contact for coupling, for example, the memory cell array 10 and the peripheral circuitry is arranged. The row decoder module 15 is electrically coupled to an interconnect (e.g., a word line WL) in the memory cell array 10 via a contact provided in the contact region C3T.

The end region ER is a rectangular toroidal region provided so as to surround an outer periphery of the wall region WR, and abuts on an outermost periphery of the semiconductor substrate 20. The end region ER suppresses, for example, hydrogen, ions, etc. generated in a thermal process for forming a stacked structure of the memory cell array 10 from entering the core region CR. Also, the end region ER can suppress, for example, moisture, etc. from permeating the core region CR from outside the end region ER. In the end region ER, crack stoppers KS1 to KS4, to be described below, are arranged. A structure in the end region ER may be removed by a dicing process of cutting a plurality of semiconductor memory devices 1 formed on a wafer into a plurality of chips. For dicing of the semiconductor memory device 1, laser-based dicing (hereinafter referred to as “stealth dicing”) may be used.

The semiconductor memory device 1 may include a kerf region KR provided so as to surround an outer periphery of the end region ER. An example of including the kerf region KR will be described in a modification, etc.

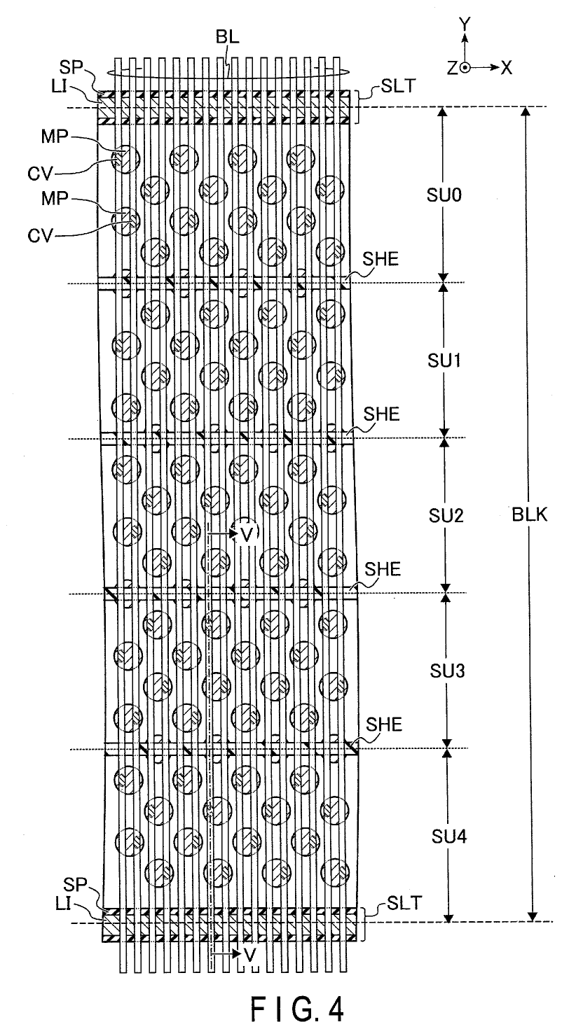

FIG. 4 is a planar view showing an example of a planar layout of the memory cell array 10 included in the semiconductor memory device 1 according to the first embodiment. In FIG. 4, a region including a single block BLK (i.e., string units SU0 to SU4) is extracted. As shown in FIG. 4, the memory cell array 10 includes a plurality of memory pillars MP, a plurality of contacts CV, a plurality of members SLT and SHE, and a plurality of bit lines BL in the core region CR.

The members SLT, each extending along the X axis, are aligned along the Y axis. Each member SLT includes a contact LI and a spacer SP. The contact LI is a conductor that extends over an XZ plane. The spacer SP is an insulator provided on a side surface of the contact LI. In other words, the contact LI is surrounded by the spacer SP in an XY planar view. Each member SLT splits stacked interconnects (e.g., word lines WL) that are adjacent to each other with the member SLT interposed therebetween.

The members SHE, each extending along an X axis, are aligned along the Y axis. In this example, four members SHE are arranged between adjacent members SLT. Each member SHE includes, for example, a structure in which an insulator is buried. Each member SHE splits select gate lines SGD that are adjacent to each other with the member SHE interposed therebetween.

In the planar layout of the memory cell array 10 described above, a region partitioned by the member SLT functions as a single block BLK. Each region divided by the members SLT and SHE and each region partitioned by the members SHE and SHE functions as a single string unit SU. Specifically, members SHE are respectively arranged, for example, between string units SU0 and SU1, between string units SU1 and SU2, between string units SU2 and SU3, and between string SU3 and SU4 adjacent to each other in a Y direction. In the memory cell array 10, a layout similar to the layout shown in FIG. 4, for example, is repeatedly arranged in the Y direction.

The planar layout of the memory cell array 10 included in the semiconductor memory device 1 according to the first embodiment is not limited to the layout described above. For example, the number of members SHE that are arranged between adjacent members SLT may be designed to be a given number. The number of string units SU formed between adjacent members SLT may be varied based on the number of members SHE arranged between the adjacent members SLT.

The memory pillars MP are arranged, for example, in a 24-row staggered manner in a region between two adjacent members SLT. For example, a single member SHE overlaps memory pillars MP in the fifth row, memory pillars MP in the tenth row, memory pillars MP in the 15th row, and memory pillars MP in the 20th row, counting from an upper side (+Y side) of the drawing. The number and arrangement of the memory pillars MP between adjacent members SLT are not limited thereto, and may be suitably varied. Each memory pillar MP functions as, for example, a single NAND string NS.

The bit lines BL, each extending along the Y direction, are aligned along the X direction. Each bit line BL is arranged so as to overlap at least one memory pillar MP in each string unit SU. In the example of FIG. 4, a case is shown where two bit lines BL are arranged so as to overlap a single memory pillar MP. A contact CV is provided between a memory pillar MP and one of the bit lines BL that overlaps the memory pillar MP. Each memory pillar MP is electrically coupled to a single bit line BL with the contact CV interposed therebetween. In each region partitioned by the member SLT or the member SHE, a single contact CV is coupled to a single bit line BL.

For example, a contact CV between a bit line BL and a memory pillar MP that is in contact with the member SHE is omitted. In other words, a contact CV between a bit line BL and a memory pillar MP that is in contact with two different select gate lines SGD is omitted. The number and arrangement of the memory pillars MP, the members SHE, etc. between adjacent members SLT are not limited to the configuration described with reference to FIG. 4, and may be suitably varied. The number of bit lines BL that overlap each memory pillar MP may be designed to be a given number.

### <1-1-4> Cross-sectional Structure of Memory Cell Array 10

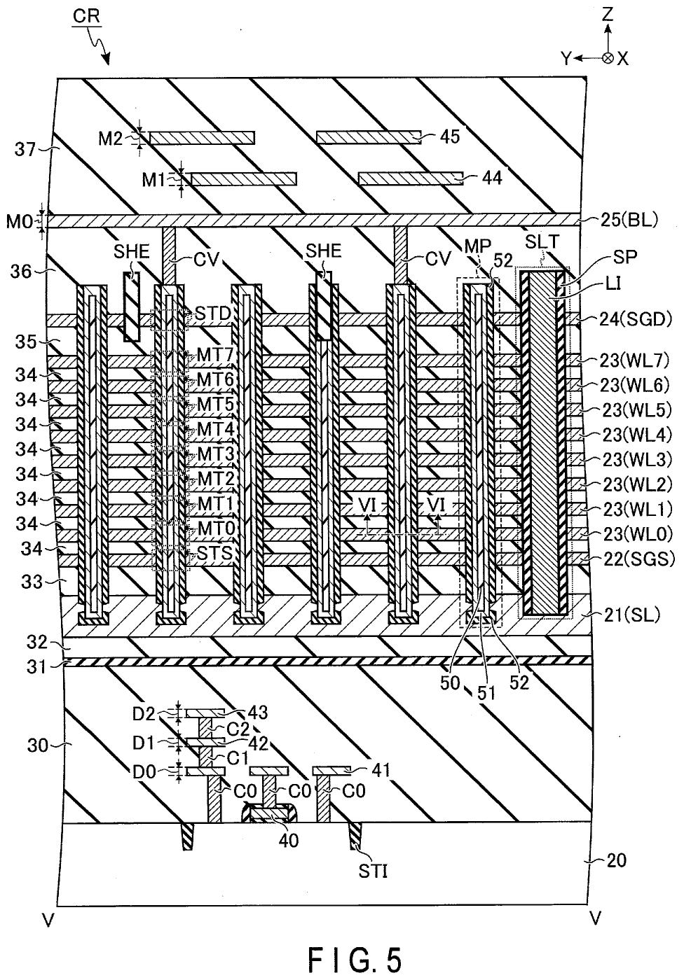

FIG. 5 is a cross-sectional view taken along line V-V of FIG. 4, showing an example of a cross-sectional structure of the core region CR in the semiconductor memory device 1 according to the first embodiment. As shown in FIG. 5, the semiconductor memory device 1 further includes, in the core region CR, a semiconductor substrate 20, conductive layers 21 to 25, and insulating layers 30 to 37, for example.

The semiconductor substrate 20 is, for example, a p-type semiconductor substrate. On an upper surface (in the vicinity of the surface) of the semiconductor substrate 20, an element isolation region STI is provided. The element isolation region STI is provided, for example, to electrically isolate an impurity diffusion region (not illustrated). In the element isolation region STI, silicon oxide, for example, is employed.

The insulating layer 30 is provided on the semiconductor substrate 20. The insulating layer 30 contains, for example, silicon oxide (SiO₂). A circuit region is provided in a part of the semiconductor substrate 20 and the insulating layer 30, and the memory cell array 10 is provided above the insulating layer 30; however, illustration of part of such a structure is omitted. In the circuit region, circuitry employed for, for example, the row decoder module 15, the sense amplifier module 16, etc. is formed. The insulating layer 30 may contain, for example, conductive layers 40 to 43 and contacts C0 to C2. Details of the insulating layer 30 will be discussed later.

The insulating layer 31 is provided on the insulating layer 30. The insulating layer 31 contains, for example, silicon nitride (SiN). The insulating layer 31 suppresses, for example, hydrogen generated in a thermal process for forming a stacked structure of the memory cell array 10 from entering the transistor provided on the semiconductor substrate 20. The insulating layer 31 may be referred to as a barrier film.

The insulating layer 32 is provided on the insulating layer 31. The insulating layer 32 contains, for example, silicon oxide. The conductive layer 21 is provided on the insulating layer 32. The conductive layer 21 is formed in, for example, a plate shape extending along an XY plane, and is used as the source line SL. The conductive layer 21 contains, for example, a metallic material or silicon (Si) doped with phosphorous (P).

The insulating layer 33 is provided on the conductive layer 21. The insulating layer 33 contains, for example, silicon oxide. The conductive layer 22 is provided on the insulating layer 33. The conductive layer 22 is formed in, for example, a plate shape extending along the XY plane. The conductive layer 22 is used as a select gate line SGS. The conductive layer 22 contains, for example, tungsten (W) or molybdenum (Mo).

A plurality of insulating layers 34 and a plurality of conductive layers 23 are stacked in an alternating manner above the conductive layer 22. Each conductive layer 23 is formed in, for example, a plate shape extending along the XY plane. The stacked conductive layers 23 are respectively used as word lines WL0 to WL7, from the side of the semiconductor substrate 20. The conductive layers 23 contain, for example, tungsten (W) or molybdenum (Mo). The insulating layers 34 contain, for example, silicon oxide.

The insulating layer 35 is provided above the topmost conductive layer 23. The insulating layer 35 contains, for example, silicon oxide. The conductive layer 24 is provided on the insulating layer 35. The conductive layer 24 is formed in, for example, a plate shape extending along the XY plane. The conductive layer 24 is used as a select gate line SGD. The conductive layer 24 contains, for example, tungsten (W) or molybdenum (Mo).

The insulating layer 36 is provided on the conductive layer 24. The insulating layer 36 contains, for example, silicon oxide. The conductive layers 25 are provided on the insulating layer 36. Each of the conductive layers 25 is formed, for example, in a line shape extending in the Y direction. The conductive layers 25 are used as bit lines BL. The conductive layers 25 are aligned in the X direction in an unillustrated region. The conductive layers 25 contain, for example, copper (Cu).

The insulating layer 37 is provided on the conductive layers 25. The insulating layer 37 contains, for example, silicon oxide. The insulating layer 37 includes an interconnect, etc. for coupling the memory cell array 10, the row decoder module 15, and the sense amplifier module 16. The insulating layer 37 may include, for example, conductive layers 44 and 45. Details of the insulating layer 37 will be discussed later.

The memory pillars MP extend along a Z direction, each penetrating the insulating layers 33 to 35 and the conductive layers 22 to 24. Upper ends of the memory pillars MP are included in the insulating layer 36. Bottom portions of the memory pillars MP are included in the conductive layer 21.

Each of the memory pillars MP includes, for example, a core member 50, a semiconductor layer 51, and a laminated film 52. The core member 50 extends in the Z direction, and is provided in a central part of the memory pillar MP. For example, an upper end of the core member 50 is included in a layer above a layer in which the conductive layer 24 is provided. A lower end of the core member 50 reaches the conductive layer 21. The core member 50 includes, for example, an insulator such as silicon oxide.

The semiconductor layer 51 covers, for example, the periphery of the core member 50. A part of the semiconductor layer 51 is in contact with, for example, the conductive layer 21 via a side surface of the memory pillar MP. The semiconductor layer 51 contains, for example, silicon.

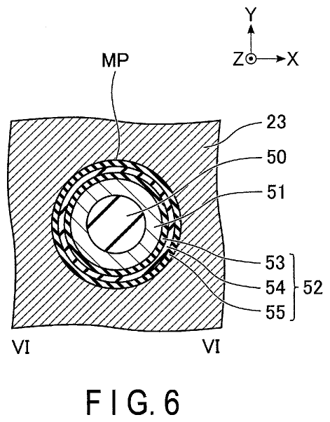

The laminated film 52 covers a side surface and a bottom surface of the semiconductor layer 51, except for a portion at which the semiconductor layer 51 and the conductive layer 21 are in contact with each other. Details of the laminated film 52 will be described with reference to FIG. 6.

In the structure of the memory pillar MP described above, a portion at which the memory pillar MP and the conductive layer 22 intersect functions as a select transistor STS. The portion at which the memory pillar MP and each conductive layer 23 intersect functions as a single memory cell transistor MT. The portion at which the memory pillar MP and the conductive layer 24 intersect functions as a select transistor STD.

The member SLT includes, for example, a portion provided along the XZ plane, and divides the conductive layers 22 to 24 and the insulating layers 33 to 35 in the Y direction. The contact LI in the member SLT is provided along the member SLT. An upper end of the contact LI is in contact with the insulating layer 36. A lower end of the contact LI is in contact with the conductive layer 21. The contact LI is used as, for example, a part of the source line SL. The spacer SP is provided at least between the contact LI and the conductive layers 22 to 24. A region between the contact LI and the conductive layers 22 to 24 is isolated and insulated by the spacer SP. The member SLT may have a structure in which a contact LI is not provided and an insulator is buried over the entirety of the member SLT.

The member SHE is, for example, provided along the XZ plane, and divides at least the conductive layer 24 in the Y direction. An upper end of the member SHE is in contact with the insulating layer 36. A lower end of the member SHE is in contact with the insulating layer 35. The member SHE includes, for example, an insulator such as silicon oxide. An upper end of the member SHE and an upper end of the member SLT may or may not be aligned. An upper end of the member SHE and an upper end of the memory pillar MP may or may not be aligned.

The contact CV of a pillar-shape is provided on an upper surface of the semiconductor layer 51 of the memory pillar MP. In an illustrated region, contacts CV coupled to two of the six memory pillars MP are depicted. Contacts CV are coupled, in an unillustrated region, to the memory pillars MP which do not overlap the members SHE and to which contacts CV are not coupled in the illustrated region.

A single conductive layer 25, namely, a single bit line BL, is in contact with an upper surface of each contact CV. Each contact CV is coupled to a single conductive layer 25 in each of the areas partitioned by the members SLT and SHE. That is, a memory pillar MP provided between adjacent members SLT and SHE and a memory pillar MP provided between two adjacent members SHE are electrically coupled to each of the conductive layers 25.

A structure of the interior of the insulating layer 30 will be described. As described above, the insulating layer 30 may contain conductive layers 40 to 43 and contacts C0 to C2. The conductive layer 40 is provided on the semiconductor substrate 20 with a gate insulation film interposed therebetween. The conductive layer 40 functions as a gate electrode of a transistor provided below the memory cell array 10. The contacts C0 are provided on the conductive layer 40 and on the semiconductor substrate 20. The contact C0 provided on the semiconductor substrate 20 is coupled to an impurity diffusion layer (not illustrated) provided in the semiconductor substrate 20. The conductive layers 41 are provided on the contacts C0. The contact C1 is provided on the conductive layer 41. The conductive layer 42 is provided on the contact C1. The contact C2 is provided on the conductive layer 42. The conductive layer 43 is provided on the contact C2. Each of the conductive layers 40 to 43 and the contacts C0 to C2 contains, for example, a metal such as tungsten.

A structure of the interior of the insulating layer 37 will be described. As described above, the insulating layer 37 may include conductive layers 44 and 45. The conductive layer 44 is provided above the conductive layers 25 so as to be distanced from the conductive layers 25. The conductive layer 45 is provided above the conductive layer 44 so as to be distanced from the conductive layer 44. Each of the conductive layers 44 and 45 contains, for example, a metal such as tungsten.

Interconnect layers in which the conductive layers 41, 42, and 43 are provided may be respectively referred to as “D0”, “D1”, and “D2”. Interconnect layers in which the conductive layers 25, 44, and 45 are provided may be respectively referred to as “M0”, “M1”, and “M2”.

FIG. 6 is a cross-sectional view taken along line VI-VI of FIG. 5, showing an example of a cross-sectional structure of a memory pillar MP in the semiconductor memory device 1 according to the first embodiment. More specifically, FIG. 6 shows a cross-sectional structure of a memory pillar MP in a layer that is parallel to a surface of the semiconductor substrate 20 and that includes the conductive layer 23. As shown in FIG. 6, the laminated film 52 includes, for example, a tunnel insulating film 53, an insulating film 54, and a block insulating film 55.

In a cross section including the conductive layer 23, the core member 50 is provided in a central part of the memory pillar MP. The semiconductor layer 51 surrounds a side surface of the core member 50. The tunnel insulating film 53 surrounds aside surface of the semiconductor layer 51. The insulating film 54 surrounds a side surface of the tunnel insulating film 53. The block insulating film 55 surrounds a side surface of the insulating film 54. The conductive layer 23 surrounds a side surface of the block insulating film 55. Each of the tunnel insulating film 53 and the block insulating film 55 contains, for example, silicon oxide. The insulating film 54 contains, for example, silicon nitride.

In each memory pillar MP described above, the semiconductor layer 51 is used as a channel (current path) of each of the memory cell transistors MT0 to MT7 and the select transistors STD and STS. The insulating film 54 is used as a charge storage layer of the memory cell transistors MT. The semiconductor memory device 1 is capable of letting a current flow between the bit line BL and the contact LI via the memory pillar MP by turning on the memory cell transistors MT0 to MT7 and the select transistors STD and STS. Thereby, each of the memory pillars MP is capable of functioning as a single NAND string NS.

### <1-1-5> Structures of Crack Stoppers KS1 and KS3

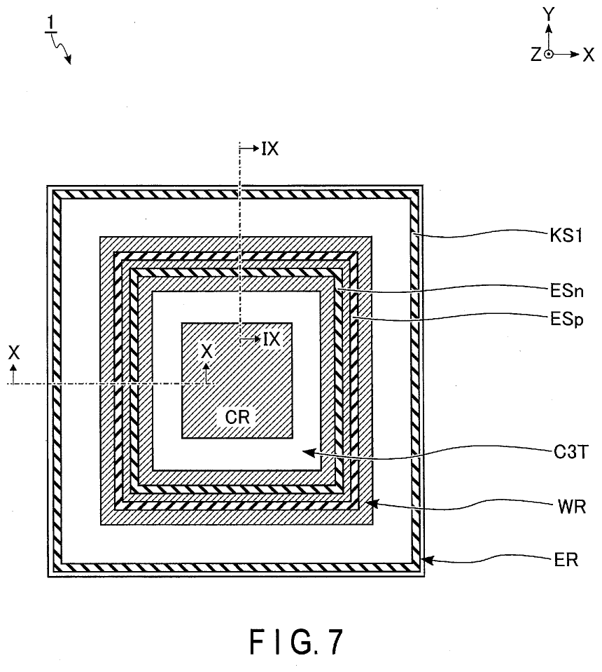

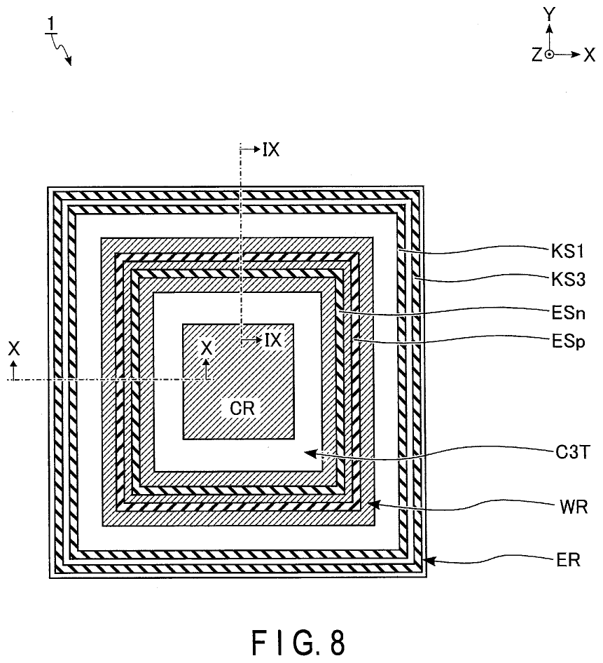

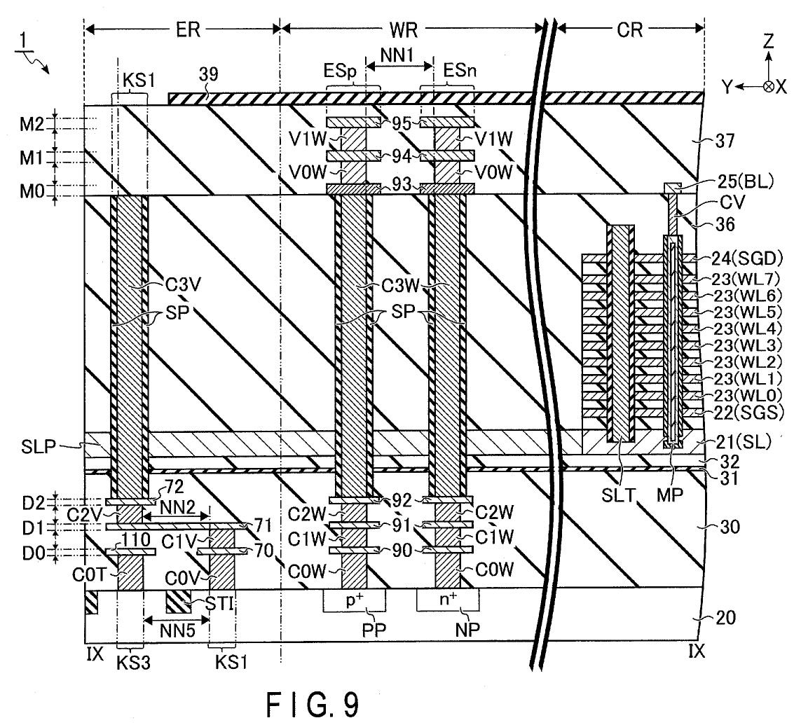

FIGS. 7 and 8 are planar views each showing an example of a planar layout of the semiconductor memory device 1 according to the first embodiment. FIGS. 7 and 8 are planar views each showing an example of a planar layout of sealing members ESn and ESp and crack stoppers KS1 and KS3. The region shown in FIGS. 7 and 8 is the same as the region shown in the planar layout of the semiconductor memory device 1 according to the first embodiment shown in FIG. 3. FIGS. 7 and 8 show layers of different coordinates on the z-axis. FIG. 7 shows, for example, an example of a structure in a layer including the insulating layer 36. FIG. 8 shows, for example, an example of a structure in a layer including a contact C0 in the insulating layer 30. Some of the cross-sectional structures of the region shown in FIGS. 7 and 8 will be described later with reference to FIG. 9. The hatching in FIGS. 7 and 8 is given only for the purpose of promoting visual understanding; thus, the hatched components are irrelevant to materials indicated by a pattern of the hatching.

As shown in FIG. 7, the layer including the insulating layer 36 of the semiconductor memory device 1 includes the sealing members ESn and ESp in the wall region WR. As shown in FIG. 8, the layer including the contact C0 of the semiconductor memory device 1 includes the sealing members ESn and ESp in the wall region WR.

As shown in FIGS. 7 and 8, each of the sealing members ESn and ESp is provided in a rectangular toroidal shape and surrounds the outer periphery of the core region CR in the wall region WR. The sealing member ESp surrounds the outer periphery of the sealing member ESn, and is distanced from the sealing member ESn. Each of the sealing members ESn and ESp extends in the Z direction in the insulating layers 36 and 30, as will be described with reference to FIG. 9.

The sealing member ESn is a structure capable of allowing the positive charge generated inside and outside the wall region WR to escape to the semiconductor substrate 20. The sealing member ESp is a structure capable of allowing the negative charge generated inside and outside the wall region WR to escape to the semiconductor substrate 20.

Also, each of the sealing members ESn and ESp can suppress moisture, etc. from permeating the core region CR from outside the wall region WR. Each of the sealing members ESn and ESp may suppress a stress generated in the interlayer insulating film (e.g., tetraethoxysilane (TEOS)) of the semiconductor memory device 1. Also, each of the sealing members ESn and ESp may be used as a stopper that suppresses propagation of cracks to the inside of the semiconductor memory device 1, in a manner similar to the crack stopper KS1. Each of the sealing members ESn and ESp may be referred to as an “edge seal”, a “crack stopper”, etc.

As shown in FIG. 7, the layer including the insulating layer 36 of the semiconductor memory device 1 includes a crack stopper KS1 in the end region ER. As shown in FIG. 8, the layer including the contacts C0 of the semiconductor memory device 1 includes crack stoppers KS1 and KS3 in the end region ER.

As shown in FIG. 7, the crack stopper KS1 is provided in a rectangular toroidal shape and surrounds an outer periphery of the wall region WR in the end region ER in the layer including the insulating layer 36.

As shown in FIG. 8, each of the crack stoppers KS1 and KS3 is provided in a rectangular toroidal shape and surrounds an outer periphery of the wall region WR in the end region ER in the layer including the contacts C0. The crack stopper KS3 surrounds an outer periphery of the crack stopper KS1, and is distanced from the crack stopper KS1.

The crack stopper KS1 has a bent structure, while extending in the Z direction, as will be described in detail later. The bent portions are included in, for example, the layer including the insulating layer 30. The crack stopper KS1, including the bent portions, is provided in a rectangular toroidal shape and surrounds an outer periphery of the wall region WR, as shown in FIG. 8. The crack stopper KS3 is included in, for example, the insulating layer 30. The insulating layer 36 does not include, for example, a crack stopper KS3. A part of the crack stopper KS1 is positioned, for example, above the crack stopper KS3 in the Z axis.

The crack stopper KS1 is a structure capable of functioning as a stopper that suppresses propagation of cracks. That is, upon generation of a crack in a peripheral portion of a chip on which the semiconductor memory device 1 is formed in a dicing process, the crack stopper KS1 can suppress the crack from reaching the inside of the semiconductor memory device 1.

The crack stopper KS1 can suppress moisture, etc. from permeating the core region CR from outside the end region ER. The crack stopper KS1 can suppress the stress generated in an interlayer insulating film of the semiconductor memory device 1. The crack stopper KS1 may also be referred to as an “edge seal”, a “sealing member”, etc.

The semiconductor memory device 1 may further include crack stoppers KS2 and KS4 in the end region ER. Examples of including the crack stoppers KS2 and KS4 will be described in a modification, etc.

FIG. 9 is a cross-sectional view taken along line IX-IX of FIGS. 7 and 8, showing an example of a cross-sectional structure of the core region CR, the wall region WR, and the end region ER in the semiconductor memory device 1 according to the first embodiment. As shown in FIG. 9, the semiconductor memory device 1 further includes a layer stack SLP and a surface protective film 39 in the wall region WR and the end region ER. The semiconductor memory device 1 includes sealing members ESn and ESp in the wall region WR. The semiconductor memory device 1 includes a crack stopper KS1 in the end region ER. The semiconductor memory device 1 may include a crack stopper KS3 in the end region ER.

The layer stack SLP is provided on the insulating layer 32. The layer stack SLP is a stacked structure used for formation of the source line SL. The layer stack SLP is provided at a height substantially identical to that of the source line SL. The layer stack SLP and the conductive layer 21 are electrically coupled, and include a continuously provided portion. The layer stack SLP contains, for example, silicon doped with phosphorous. The layer stack SLP is provided, for example in all of the core region CR, the wall region WR, and the end region ER. The layer stack SLP in the core region CR includes a conductive layer 21, and functions as the source line SL. It suffices that the layer stack SLP is provided at least in the core region CR. The layer stack SLP provided in a region other than the core region CR may be utilized in the manufacturing process of the semiconductor memory device 1. The insulating layer 36 is provided above the layer stack SLP in the wall region WR and the end region ER.

The surface protective film 39 is provided above the insulating layer 37. The surface protective film 39 is provided in a region that is inside of an upper portion and above an upper end of the crack stopper KS1 and that is other than a region in which a terminal for coupling with the exterior is provided. In other words, the surface protective film 39 is not provided in a region above the contact C3V that forms the crack stopper KS1 in the end region ER in the layer including the insulating layer 36. The surface protective film 39 is provided above the insulating layer 37 in the core region CR, but the surface protective film 39 is not provided at a position above a region that is outside of the contact C3V, or that is further distanced from the core region CR than at least the contact C3V; however, illustration of such a configuration is omitted in FIG. 5. The surface protective film 39 protects the semiconductor memory device 1 from moisture, dust, etc. The surface protective film 39 contains, for example, a resin material such as polyimide.

Each of the sealing members ESn and ESp extends in the Z direction. Each of the sealing members ESn and ESp splits the insulating layers 30 to 32, the layer stack SLP, the insulating layer 36, and a part of the insulating layer 37. Each of the sealing members ESn and ESp includes conductive layers 90 to 95 and contacts COW, C1W, C2W, C3W, V0W, and V1W. The semiconductor substrate 20 includes, in the wall region WR, an n-type impurity diffusion region NP and a p-type impurity diffusion region PP.

The sealing member ESn is provided on the n-type impurity diffusion region NP. The conductive layer 90 is provided on the n-type impurity diffusion region NP with the contact COW interposed therebetween. The conductive layer 91 is provided on the conductive layer 90 with the contact ClW interposed therebetween. The conductive layer 92 is provided on the conductive layer 91 with the contact C2W interposed therebetween. The conductive layer 93 is provided on the conductive layer 92 with the contact C3W interposed therebetween. The conductive layer 94 is provided on the conductive layer 93 with the contact V0W interposed therebetween. The conductive layer 95 is provided on the conductive layer 94 with the contact V1W interposed therebetween.

The conductive layers 90, 91, 92, 93, 94, and 95 are respectively included in the interconnect layers D0, D1, D2, M0, M1, and M2. A set of the contacts COW, C1W, C2W, and C3W and the conductive layers 90, 91, and 92 splits the insulating layers 30 to 32, the layer stack SLP, and the insulating layer 36. A set of the contacts V0W and V1W and the conductive layers 93, 94, and 95 splits a part of the insulating layer 37. The spacer SP is provided on a side surface of the contact C3W. The spacer SP may or may not be provided.

The sealing member ESp is provided on the p-type impurity diffusion region PP. The conductive layer 90 is provided on the p-type impurity diffusion region PP with the contact COW interposed therebetween. The position at which the contact COW of the sealing member ESp is provided is further distanced from the core region CR than the position at which the contact COW of the sealing member ESn is provided. A structure above the conductive layer 90 is similar to that of the sealing member ESn, and a description thereof will be omitted.

In an unillustrated region, a set of the contacts COW, C1W, C2W, C3W, V0W, and V1W and the conductive layers 90 to 95 includes a portion extending in the Y direction. The set of the contacts COW, C1W, C2W, C3W, V0W and V1W, and the conductive layers 90 to 95 also includes a portion extending in the X direction. Thereby, the set of the contacts COW, C1W, C2W, C3W, V0W, and V1W and the conductive layers 90 to 95 is provided, for example, in a rectangular toroidal shape and surrounds the core region CR in an XY planar view (top view). Each of the contacts COW, C1W, C2W, C3W, V0W, and V1W and the conductive layers 90 to 95 contains, for example, a metal such as tungsten. The spacer SP is, for example, a silicon oxide film. Each of the sealing members ESn and ESp may be regarded as a wall between the core region CR and an outer edge of the semiconductor memory device 1. The contacts C3W of the sealing members ESn and ESp are distanced from each other by, for example, a distance NN1 in an XY planar view. In other words, in a cross section taken along line TX-IX, namely, in a YZ planar view, the contacts C3W of the sealing members ESn and ESp are distanced from each other by the distance NN1 in the Y direction.

It suffices that the sealing member ESn is connected at least to the n-type impurity diffusion region NP. It suffices that the n-type impurity diffusion region NP has a sufficient region as a discharge path, and need not necessarily be provided in a rectangular toroidal shape. The n-type impurity diffusion region NP is formed in, for example, a p-type well region of the semiconductor substrate 20. Similarly, it suffices that the sealing member ESp is connected at least to the p-type impurity diffusion region PP. It suffices that the p-type impurity diffusion region PP has a sufficient region as a discharge path, and the p-type impurity diffusion region PP need not necessarily be provided in a rectangular toroidal shape. The p-type impurity diffusion region PP is formed in, for example, a p-type well region of the semiconductor substrate 20.

The crack stopper KS1 has a bent structure, while extending in the Z direction. The crack stopper KS1 splits the insulating layers 30 to 32, the layer stack SLP, and the insulating layer 36.

The crack stopper KS1 includes conductive layers 70 to 72 and contacts C0V to C3V. The conductive layer 70 is provided on the semiconductor substrate 20 with the contact C0V interposed therebetween. The conductive layer 71 is provided on the conductive layer 70 with the contact C1V interposed therebetween. The conductive layer 71 is formed to have a greater width than the conductive layer 70 in a direction away from the core region CR in an XY planar view. In other words, in a cross section taken along line IX-IX, the length of the conductive layer 71 in the Y direction is greater than that of the conductive layer 70, and extends in a +Y direction (direction away from the core region CR).

The conductive layer 72 is provided on the conductive layer 71 with the contact C2V interposed therebetween. The contact C3V is provided on the conductive layer 72. The positions at which the contacts C2V and C3V are provided are further distanced from the core region CR than the positions at which the contacts C0V and C1V are provided. The contacts C2V and C3V and the contacts C0V and C1V are distanced from each other by, for example, a distance NN2. In other words, in a cross section taken along line IX-IX, the contacts C2V and C3V are distanced from the contacts C0V and C1V by a distance NN2 in the +Y direction. The distance NN1 and the distance NN2 may be substantially identical in length. In this manner, the crack stopper KS1 bends in the insulating layer 30.

The conductive layers 70, 71, and 72 are respectively included in the interconnect layers D0, D1, and D2. A set of the contacts C0V and C1V and the conductive layers 70 and 71 splits the insulating layer 30 halfway. A set of the contacts C3V and C2V and the conductive layers 71 and 72 splits a part of the insulating layer 30, the insulating layers 31 and 32, the layer stack SLP, and the insulating layer 36. A spacer SP is provided on a side surface of the contact C3V. The spacer SP may not be provided, which will be described in detail below in a modification.

In an unillustrated region, a set of the conductive layers 70 to 72 and the contacts C0V to C3V includes a portion extending in the Y direction. The set of the conductive layers 70 to 72 and the contacts C0V to C3V also includes a portion extending in the X direction. Thereby, the set of the conductive layers 70 to 72 and the contacts C0V to C3V is provided, for example, in a rectangular toroidal shape and surrounds the core region CR in an XY planar view. Each of the conductive layers 70 to 72 and the contacts C0V to C3V contains, for example, a metal such as tungsten. The spacer SP is, for example, a silicon oxide film. The crack stopper KS1 may be regarded as a wall between the core region CR and the kerf region KR.

The crack stopper KS3 extends in the Z direction. The crack stopper KS3 splits, for example, a part of the insulating layer 30.

The crack stopper KS3 includes a conductive layer 110 and a contact COT. The conductive layer 110 is provided on the semiconductor substrate 20 with the contact COT interposed therebetween.

The position at which the contact COT is provided is further distanced from the core region CR than the position at which the contact C0V is provided. The contacts COT and C0V are distanced from each other by, for example, a distance NN5. In other words, in a cross section taken along line IX-IX, the contact COT is distanced from the contact C0V by a distance NN5 in the +Y direction. The distance NN5 may be substantially identical in length to the distance NN1 and/or the distance NN2. That is, the contact C3V may be positioned above the contact COT in the Z axis.

The conductive layer 110 is included in the interconnect layer D0. A set of the conductive layer 110 and the contact COT splits a part of the insulating layer 30.

In an unillustrated region, a set of the conductive layer 110 and the contact COT includes a portion extending in the Y direction. The set of the conductive layer 110 and the contact COT also includes a portion extending in the X direction. Thereby, the set of the conductive layer 110 and the contact COT is provided, for example, in a rectangular toroidal shape and surrounds the core region CR in an XY planar view. Each of the conductive layer 110 and the contact COT contains, for example, a metal such as tungsten.

The crack stopper KS3 may have a structure other than the above-described one. Such an example will be described in a modification.

The semiconductor substrate 20 may include an element isolation region STI in the end region ER. The element isolation region STI is provided, for example, in a region of an upper surface (vicinity of the surface) of the semiconductor substrate 20 on which the contacts C0V and COT do not abut. The number of element isolation regions STI included in the end region ER may be either one or more than one.

The element isolation region STI is provided, for example, in a region between a portion on which the contact C0V abuts and a portion on which the contact COT abuts. In other words, the element isolation region STI is provided in, for example, a region that is below a region between a region below the contact C3V and the contact C0V and that includes an upper surface of the substrate. Furthermore, the element isolation region STI is provided, for example, in a region further distanced from the core region CR than the portion on which the contact COT abuts. The region in which the element isolation region STI is provided may include an outer edge of the semiconductor substrate 20.

In an unillustrated region, the element isolation region STI includes a portion extending in the Y direction. The element isolation region STI also includes a portion extending in the X direction. Thereby, the element isolation region STI is provided, for example, in a rectangular toroidal shape and surrounds the core region CR in an XY planar view. Alternatively, the element isolation region STI may be provided, for example, in a discrete manner along a rectangular toroidal shape in an XY planar view. In this case, the element isolation region STI surrounds the core region CR in a discrete rectangular toroidal shape in an XY planar view. In the element isolation region STI, silicon oxide, for example, is employed.

The description given above with reference to FIG. 9 relates to a cross section taken along line IX-IX of FIG. 8. The cross section taken along line X-X of FIG. 8 is similar to that of FIG. 9 with the X axis replaced with the Y axis and the Y axis replaced with the X axis. Similarly, the details of the cross section taken along line X-X of FIG. 8 are similar to those of FIG. 9 with the X axis replaced with the Y axis and the Y axis replaced with the X axis.

### <1-2> Method of Manufacturing Semiconductor Memory

### Device 1

Hereinafter, an example of a process relating to dicing, in the process of manufacturing the semiconductor memory device 1 according to the first embodiment, will be described. The process to be described below is based on an example in which stealth dicing is used. An example in which blade dicing is used will be described below in a modification.

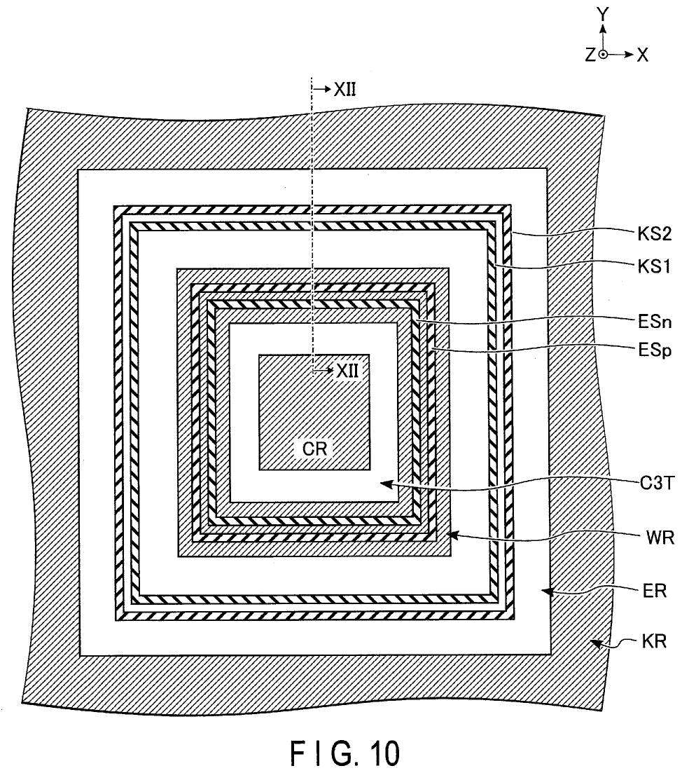

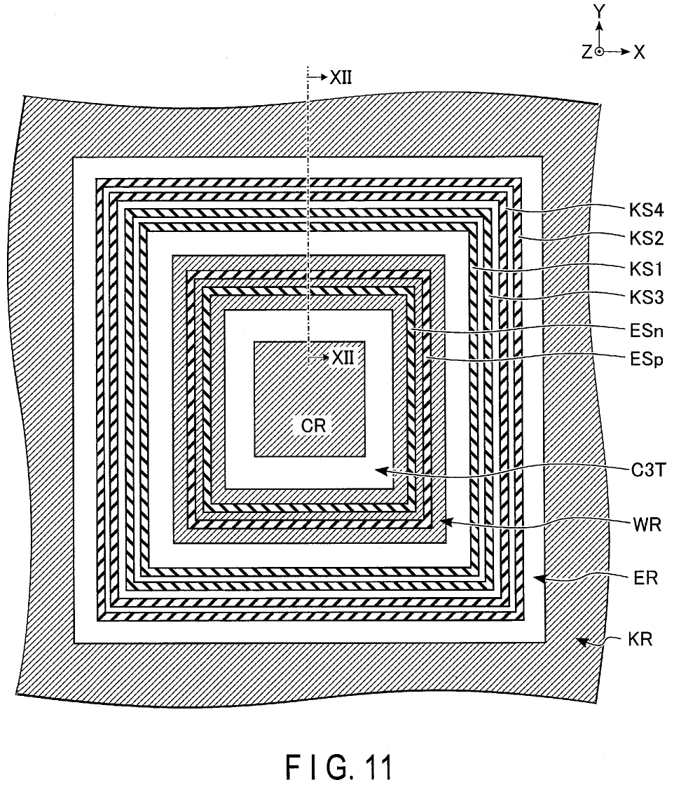

A structure of the semiconductor memory device 1 prior to dicing will be described with reference to FIGS. 10 to 12. FIGS. 10 and 11 show a planar layout of the semiconductor memory device 1 prior to dicing. FIGS. 10 and 11 show a region including a planar layout of the sealing members ESn and ESp and the crack stoppers KS1 and KS3 shown in FIGS. 7 and 8. FIGS. 10 and 11 show layers at the same coordinates in the Z axis as those of FIGS. 7 and 8, respectively.

As shown in FIGS. 10 and 11, the semiconductor memory device 1 during manufacturing further includes a kerf region KR. The kerf region KR is a rectangular toroidal region provided to surround the outer periphery of the end region ER. In a plurality of semiconductor memory devices 1 formed on a wafer, the kerf region KR is arranged between, for example, adjacent semiconductor memory devices 1. In the kerf region KR, an alignment mark, a guard ring, etc. used in, for example, manufacturing the semiconductor memory device 1 are provided. A structure in the kerf region KR may be removed by a dicing process.

As shown in FIG. 10, a structure inside the crack stopper KS1 is similar to that described with reference to FIG. 7, and a description thereof will be omitted. As shown in FIG. 10, the layer including the insulating layer 36 of the semiconductor memory device 1 further includes the crack stopper KS2 in the end region ER.

The crack stopper KS2 is provided in a rectangular toroidal shape and surrounds an outer periphery of the crack stopper KS1 in the end region ER in the layer including the insulating layer 36. The crack stopper KS2 is distanced from the crack stopper KS1.

As shown in FIG. 11, a structure inside the crack stopper KS3 is similar to that described with reference to FIG. 8, and a description thereof will be omitted. As shown in FIG. 11, the layer including the contact C0 of the semiconductor memory device 1 further includes the crack stoppers KS2 and KS4 at the end region ER.

Each of the crack stoppers KS2 and KS4 is provided in a rectangular toroidal shape and surrounds an outer periphery of the crack stopper KS3 in the end region ER in the layer including the contact C0. The crack stopper KS4 surrounds an outer periphery of the crack stopper KS3, and is distanced from the crack stopper KS3. The crack stopper KS2 surrounds an outer periphery of the crack stopper KS4, and is distanced from the crack stopper KS4.

The crack stopper KS2 has a bent structure, while extending in the Z direction, as will be described in detail later. The bent portions are included in, for example, the layer including the insulating layer 30. The crack stopper KS2, including the bent portions, is provided in rectangular toroidal shape and surrounds an outer periphery of the wall region WR, as shown in FIG. 11. The crack stopper KS4 is included in the insulating layer 30, similarly to the crack stopper KS3. The insulating layer 36 does not include, for example, a crack stopper KS4. A part of the crack stopper KS2 is positioned, for example, above the crack stopper KS4 in the Z axis.

The crack stopper KS2 is a structure capable of functioning as a stopper that suppresses propagation of cracks, similarly to the crack stopper KS1. Also, the crack stopper KS2 can suppress a stress generated in an interlayer insulating film of the semiconductor memory device 1. The crack stopper KS2 may be referred to as an “edge seal”, a “sealing member”, etc.

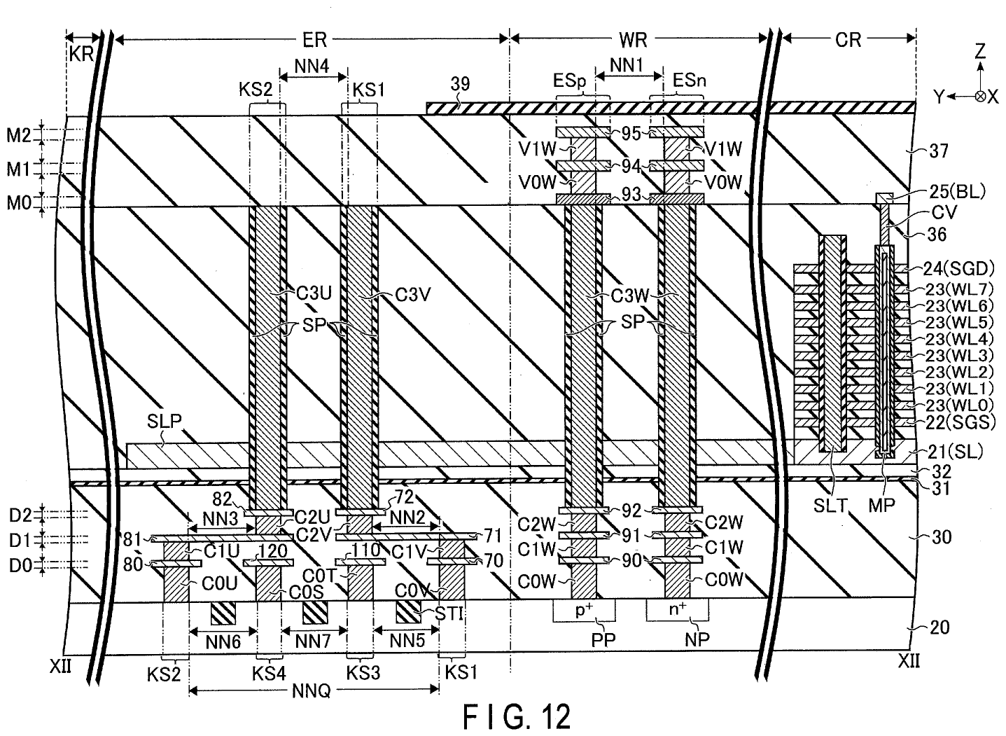

FIG. 12 is a cross-sectional view taken along line XII-XII of FIGS. 10 and 11. That is, FIG. 12 shows a cross-sectional structure of the semiconductor memory device 1 prior to dicing. As shown in FIG. 12, a structure closer to the core region CR than the crack stoppers KS1 and KS3 is similar to that described with reference to FIG. 9, and a description thereof will be omitted.

The crack stopper KS2 has a bent structure, while extending in the Z direction. The crack stopper KS2 is further distanced from the core region CR than the crack stopper KS1 in an XY planar view. The crack stopper KS2 splits the insulating layers 30 to 32, the layer stack SLP, and the insulating layer 36.

The crack stopper KS2 includes conductive layers 80 to 82 and contacts C0U to C3U. The conductive layer 80 is provided on a semiconductor substrate 20 with the contact C0U interposed therebetween. The position at which the contact C0U is provided is distanced from the position at which the contact C0V is provided by a distance NNQ in a direction away from the core region CR. The conductive layer 81 is provided on the conductive layer 80 with the contact C1U interposed therebetween. The conductive layer 81 is formed to have a greater width in an XY planar view than the conductive layer 80, stretching out in a direction approaching the core region CR. In other words, in a cross section taken along line XII-XII, the length of the conductive layer 81 in the Y direction is greater than that of the conductive layer 80, and extends in a −Y direction (direction approaching the core region CR).

The conductive layer 82 is provided on the conductive layer 81 with the contact C2U interposed therebetween. The contact C3U is provided on the conductive layer 82. The positions at which the contacts C2U and C3U are provided are closer to the core region CR than the positions at which the contacts C0U and C1U are provided. The position at which the contact C3U is provided is further distanced from the core region CR than the position at which the contact C3V is provided. The contacts C2U and C3U and the contacts C0U and C1U are distanced from each other by, for example, a distance NN3. The contacts C3U and C3V are distanced from each other by, for example, a distance NN4.

In other words, in a cross section taken along line XII-XII, contacts C2U and C3U are distanced from the contacts C0U and C1U by a distance NN3 in the −Y direction. In a cross section taken along line XII-XII, the contact C3U is distanced from the contact C3V in the +Y direction by a distance NN4. The distances NN3 and NN4 may be substantially identical in length to the distances NN1, NN2, and/or NN5. In this manner, the crack stopper KS2 bends in the insulating layer 30.

The conductive layers 80, 81, and 82 are respectively included in interconnect layers D0, D1, and D2. A set of the contacts C0U and C1U and the conductive layers 80 and 81 splits the insulating layer 30 halfway. The set of the contacts C3U and C2U and the conductive layers 81 and 82 splits a part of the insulating layer 30, the insulating layers 31 and 32, the layer stack SLP, and the insulating layer 36. A spacer SP is provided on a side surface of the contact C3U. The spacer SP may or may not be provided.

In an unillustrated region, a set of the conductive layers 80 to 82 and the contacts C0U to C3U includes a portion extending in the Y direction. The set of the conductive layers 80 to 82 and the contacts C0U to C3U also includes a portion extending in the X direction. Thereby, the set of the conductive layers 80 to 82 and the contacts C0U to C3U is provided, for example, in a rectangular toroidal shape and surrounds the core region CR in an XY planar view. Each of the conductive layers 80 to 82 and the contacts C0U to C3U contains, for example, a metal such as tungsten. The spacer SP is, for example, a silicon oxide film. The crack stopper KS2 may be regarded as a wall between the core region CR and the kerf region KR.

The contact C3W, the contact C3V, and the contact C3U may be collectively formed. Accordingly, the heights of the contact C3W, the contact C3V, and the contact C3U are substantially aligned. In other words, an upper surface of the contact C3W, an upper surface of the contact C3V, and an upper surface of the contact C3U are substantially equal in height.

The distance NNQ between the contact C0V and the contact C0U is greater than the distance NN4 between the contact C3V and the contact C3U. That is, a distance between the crack stopper KS1 and the crack stopper KS2 is greater in a lower portion and is smaller in an upper portion as viewed in the Z axis.

The crack stopper KS4 extends in the Z direction. The crack stopper KS4 splits, for example, a part of the insulating layer 30. The crack stopper KS4 includes a conductive layer 120 and a contact COS. The conductive layer 120 is provided on the semiconductor substrate 20 with the contact COS interposed therebetween. The crack stopper KS4 is positioned between the crack stopper KS2 and the crack stopper KS3 in an XY planar view.

The position at which the contact COS is provided is further distanced from the core region CR than the position at which the contact COT is provided. The position at which the contact COS is provided is closer to the core region CR than the position at which the contact C0U is provided. That is, the positions at which the contacts C0U, COS, COT, and C0V are provided are increasingly distanced from the core region CR in this order. The contacts COS and C0U are distanced from each other by, for example, a distance NN6. The contacts COS and COT are distanced from each other by, for example, a distance NN7.

In a cross section taken along line XII-XII, the contact COS is distanced from the contact C0U in the −Y direction by the distance NN6. In a cross section taken along line XII-XII, the contact COS is distanced from the contact COT in the +Y direction by the distance NN7. The distances NN6 and NN7 may be substantially identical in length to the distances NN1, NN2, NN3, NN4, and/or NN5. That is, the contact C3U may be positioned above the contact COS in the Z axis. Each of the crack stoppers KS3 and KS4 is not positioned below a region between the contact C3V and the contact C3U.

The conductive layer 120 is included in the interconnect layer D0. A set of the conductive layer 120 and the contact COS splits a part of the insulating layer 30.

In an unillustrated region, a set of the conductive layer 120 and the contact COS includes a portion extending in the Y direction. The set of the conductive layer 120 and the contact COS also includes a portion extending in the X direction. Thereby, the set of the conductive layer 120 and the contact COS is provided, for example, in a rectangular toroidal shape and surrounds the core region CR in an XY planar view. Each of the conductive layer 120 and the contact COS contains, for example, a metal such as tungsten.

The contacts COW, C0V, C0U, COT, and COS may be collectively formed. Accordingly, the heights of the contacts COW, C0V, C0U, COT, and COS may be substantially aligned. In other words, upper surfaces of the contacts COW, C0V, C0U, COT, and COS are substantially equal in height.

The crack stoppers KS3 and KS4 may have a structure other than the above-described structure. Such an example will be described in a modification.

The element isolation region STI may be provided, for example, in a region of an upper surface (vicinity of the surface) of the semiconductor substrate 20 on which the contacts C0U and COS do not abut. The element isolation region STI is provided, for example, in a region between the portion on which the contact COT abuts and the portion on which the contact COS abuts. That is, the element isolation region STI may be provided below the region between the contact C3V and the contact C3U. Furthermore, the element isolation region STI is provided, for example, in a region between the portion on which the contact COS abuts and the portion on which the contact C0U abuts.

By dicing the semiconductor memory device 1 prior to dicing, as described with reference to FIGS. 10 to 12, the semiconductor memory device 1 is manufactured. Hereinafter, an example of a stealth dicing process in the semiconductor memory device 1 will be described.

First, a laser used for dicing is applied to a portion of the semiconductor substrate 20 below the region between the contact C3V and the contact C3U. The portion to which a laser is applied becomes a starting point of stealth dicing.

Subsequently, a tensile stress, etc. is applied to a wafer including the semiconductor memory device 1, generating a crack in the vicinity of the portion to which the laser is applied. The generated crack propagates upward in the Z axis, and divides the insulating layers 30 to 32, the layer stack SLP, the insulating layer 36, and the insulating layer 37, thus dividing the wafer. A portion of the divided wafer that includes the core region CR becomes the semiconductor memory device 1.

It is ideal that a crack pass through the region between the contact C3V and the contact C3U. In this case, the semiconductor memory device 1 has a structure described with reference to FIG. 9. That is, in the case of ideal propagation of a crack, the semiconductor memory device 1 includes crack stoppers KS1 and KS3, and includes neither crack stoppers KS2 and KS4 nor a kerf region KR.

The semiconductor memory device 1 may include a crack stopper KS2 or KS4 or a kerf region KR, depending on the dicing method or the propagation direction of the crack.

Such a case will be described in a modification.

### <1-3> Advantages (Advantageous Effects) of First Embodiment

With the semiconductor memory device 1 according to the first embodiment described above, it is possible to improve a yield of the semiconductor memory device 1. Hereinafter, detailed advantageous effects of the semiconductor memory device 1 according to the first embodiment will be described.

For dicing of a semiconductor memory device, there is a demand for using stealth dicing, as well as blade dicing. Stealth dicing may tend to cause propagation of a crack generated in dicing in the X and/or Y direction, compared to blade dicing. If the degree of propagation of the crack is large, the core region CR may be damaged. Accordingly, a crack stopper capable of further suppressing damage to the core region CR caused by the crack is desired.

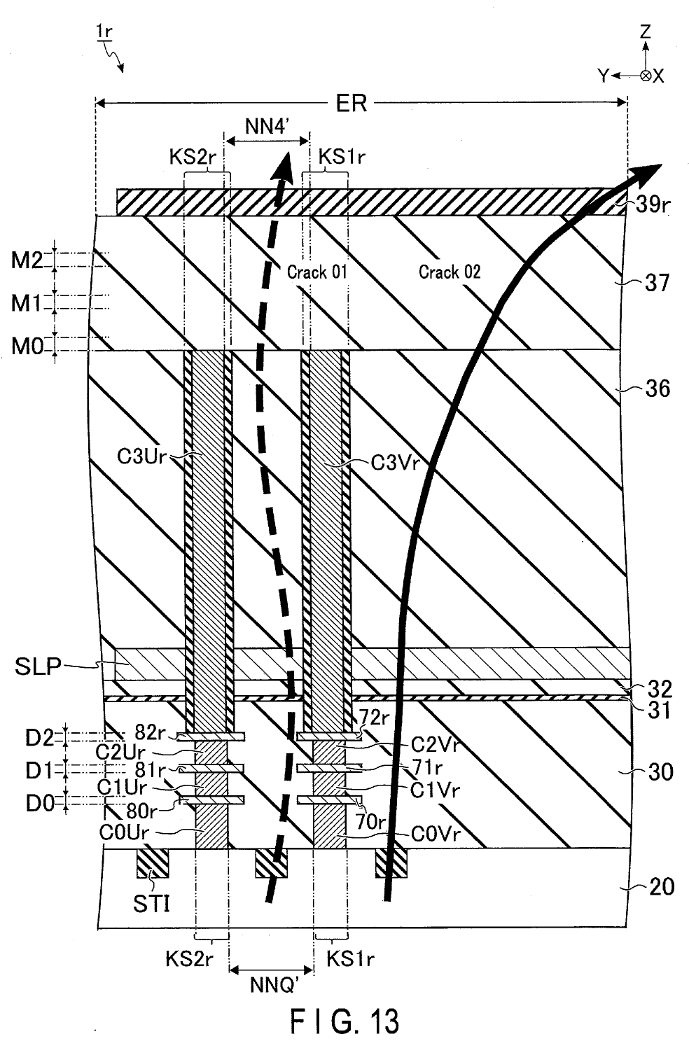

Hereinafter, a semiconductor memory device 1 according to a comparative example of the first embodiment will be described with reference to FIG. 13. The semiconductor memory device 1 and the crack stoppers KS1 and KS2 according to the comparative example of the first embodiment may be referred to as a “semiconductor memory device 1r” and “crack stoppers KS1r and KS2r”, respectively. FIG. 13 shows an example of a cross-sectional structure of a semiconductor memory device 1r according to a comparative example of the first embodiment. In FIG. 13, the end region ER in the same region as that in FIG. 9 is extracted.

The semiconductor memory device 1r differs from the semiconductor memory device 1 (FIG. 9) mainly in the absence of the crack stoppers KS3 and KS4 and the shape of the crack stoppers KS1r and KS2r.

The crack stoppers KS1r and KS2r extend in the Z direction. Each of the crack stopper KS1r and KS2r does not bend in the Z direction, unlike the crack stoppers KS1 and KS2. Each of the crack stoppers KS1r and KS2r splits the insulating layers 30 to 32, the layer stack SLP, and the insulating layer 36.

The crack stopper KS1r includes conductive layers 70r to 72r and contacts C0Vr to C3Vr. A conductive layer 70r is provided on a semiconductor substrate 20 with the contact C0Vr interposed therebetween. The conductive layer 71r is provided on the conductive layer 70r with the contact C1Vr interposed therebetween. The conductive layer 72r is provided on the conductive layer 71r with the contact C2Vr interposed therebetween. A contact C3Vr is provided on the conductive layer 72r.

The conductive layer 71r has a width in an XY planar view substantially identical to those of the conductive layers 70r and 72r. In other words, in a cross section depicted in FIG. 13, the conductive layer 71r has a length in the Y direction substantially identical to those of the conductive layers 70r and 72r. The positions at which the contacts C2Vr and C3Vr are provided are above the positions at which the contacts C0Vr and C1Vr are provided in the Z axis.

In an unillustrated region, a set of the conductive layers 70r to 72r and the contacts C0Vr to C3Vr includes a portion extending in the Y direction. The set of the conductive layers 70r to 72r and the contacts C0Vr to C3Vr also includes a portion extending in the X direction. Thereby, the set of the conductive layers 70r to 72r and the contacts C0Vr to C3Vr is provided, for example, in a rectangular toroidal shape and surrounds the core region CR.

As for the other materials, etc., the crack stopper KS1r is similar to the crack stopper KS1, and a description thereof will be omitted.

The crack stopper KS2r is provided to be further distanced from the core region CR than the crack stopper KS1r in an XY planar view. The crack stopper KS2r includes conductive layers 80r to 82r and contacts C0Ur to C3Ur. The position at which the contact C0Ur is provided is further distanced from the core region CR than the position at which the contact C0Vr is provided. The structures of the conductive layers 80r to 82r and the contacts C0Ur to C3Ur are similar to those of the conductive layers 70r to 72r and the contacts C0Vr to C3Vr, respectively, and a description thereof will be omitted.

In the semiconductor memory device 1r, a distance NNQ′ between the contact C0Vr and the contact C0Ur is substantially equal to a distance NN4′ between the contact C3Vr and the contact C3Ur. That is, a distance between upper portions of the crack stoppers KS1r and KS2r and lower portions of the crack stoppers KS1r and KS2r as viewed in the Z axis is substantially identical. The distances NNQ′ and NN4′ are, for example, substantially identical in length to the distance NN4.

At the time of performing stealth dicing, a crack generated in the semiconductor substrate 20 propagates in a +Z direction, and divides the insulating layers 30 to 32, the layer stack SLP, the insulating layer 36, and the insulating layer 37, thus dividing the wafer. At this time, if the crack propagates with a large deviation in the X direction and/or Y direction, the core region CR may be damaged. To prevent the crack from propagating in the X direction and/or Y direction, the semiconductor memory device 1r according to a comparative example of the first embodiment includes the crack stoppers KS1r and KS2r.

The crack stoppers KS1r and KS2r guide a crack generated in the region between the crack stoppers KS1r and KS2r, such as a crack 01, in the Z direction. Being guided in the Z direction by the crack stoppers KS1r and KS2r, the tendency of the crack 01 to propagate in the X direction and/or Y direction is reduced.

However, it may be difficult for the crack stoppers KS1r and KS2r to guide, in the Z direction, a crack generated in or deviated toward a region closer to the core region CR than the crack stopper KS1r, such as a crack 02. The crack 02 may propagate toward the core region CR if it cannot be guided in the Z direction by the crack stoppers KS1r and KS2r.

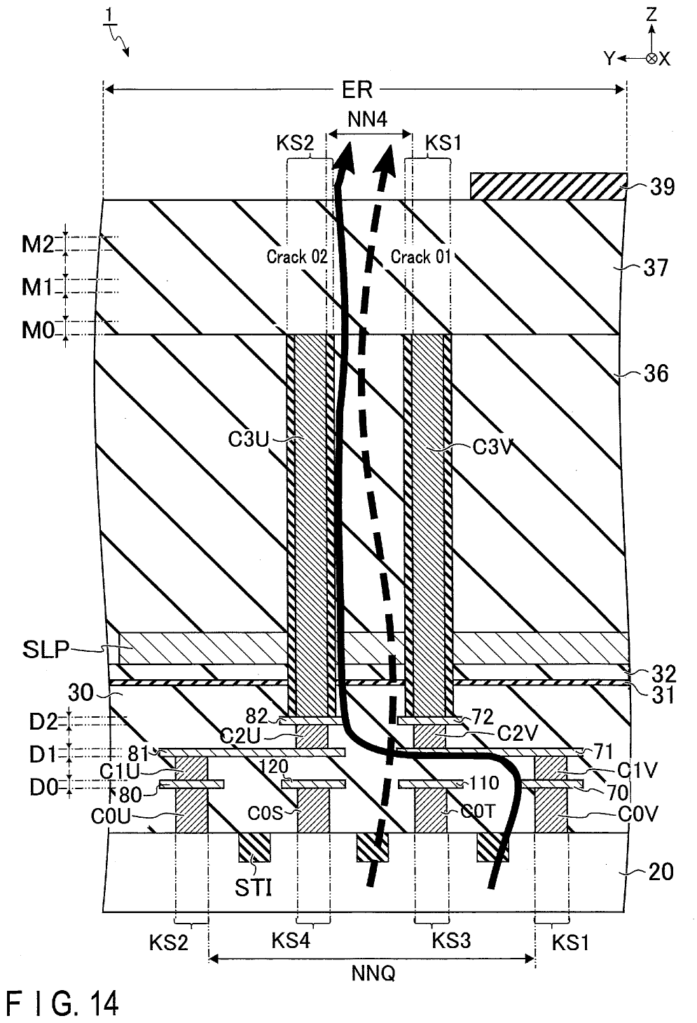

On the other hand, in the semiconductor memory device 1 according to the first embodiment, the shape of the crack stoppers KS1 and KS2 is designed in such a manner that a crack can be effectively guided. FIG. 14 shows an example of a cross-sectional structure of the semiconductor memory device 1 during manufacturing according to the first embodiment. FIG. 14 shows the same region as that in FIG. 13. As stated above, in the semiconductor memory device 1, the distance NNQ between the contact C0V and the contact C0U is greater than the distance NN4 between the contact C3V and the contact C3U. Also, a distance between the crack stopper KS1 and the crack stopper KS2 is greater in a lower portion and is smaller in an upper portion as viewed in the Z axis.

That is, the distance NNQ is greater than the distance NNQ′. Accordingly, a region between the crack stoppers KS1 and KS2 in the vicinity of the semiconductor substrate 20 of the insulating layer 30 is wider than a region between the crack stoppers KS1r and KS2r. Since the region between the crack stoppers KS1 and KS2 in the vicinity of the semiconductor substrate 20 is wide, a crack (e.g., the crack 02) that cannot propagate in the region between the crack stoppers KS1r and KS2r may be allowed to propagate in the region between the crack stoppers KS1 and KS2.

As shown in FIG. 14, since the distance NNQ is greater than the distance NNQ′, the crack 02 may propagate in the region between the crack stoppers KS1 and KS2. The crack 02 is guided in the Z direction by the crack stoppers KS1 and KS2. Accordingly, the crack 02 does not propagate in the X direction and/or Y direction, similarly to the crack 01.

In this manner, the crack stoppers KS1 and KS2 in the semiconductor memory device 1 according to the first embodiment are capable of guiding a crack in the Z direction effectively, compared to the crack stoppers KS1r and KS2r in the semiconductor memory device 1r according to the comparative example. That is, the crack stoppers KS1 and KS2 are capable of suppressing damage to the core region CR caused by the crack effectively, compared to the crack stoppers KS1r and KS2r.

Also, with the crack stoppers KS3 and KS4 included, the semiconductor memory device 1 according to the first embodiment is capable of guiding a crack in the Z direction further effectively. If, for example, a crack propagates to a region close to the crack stopper KS1, as in the crack 02, the crack can be guided in the Z direction and toward a region between the contact C3V and the contact C3U smoothly in the case where the crack stopper KS3 is provided, compared to the case where the crack stopper KS3 is not provided. In this manner, the semiconductor memory device 1 according to the first embodiment is capable of guiding a crack in the Z direction simply by including the crack stoppers KS1 and KS2, but is capable of guiding a crack in the Z direction further effectively by including the crack stoppers KS3 and KS4.

Also, with the element separation region STI included, the semiconductor memory device 1 according to the first embodiment is capable of guiding a crack in the Z direction further effectively. As described with reference to FIGS. 9 and 12, the element isolation region STI is provided in, for example, the region between the portion on which the contact C0V abuts and the portion on which the contact COT abuts, the region between the portion on which the contact COT abuts and the portion on which the contact COS abuts, and/or the region between the portion on which the contact COS abuts and the portion on which the contact C0U abuts.

In this manner, by partially providing the element isolation region STI, the semiconductor memory device 1 according to the first embodiment is capable of guiding a crack to a portion in which the element isolation region STI is provided. In propagation of the crack generated in the semiconductor substrate 20 toward the insulating layer 30 in the semiconductor substrate 20, the crack is likely to be guided to a region in which the element isolation region STI is provided, rather than a region in which the element isolation region STI is not provided. Accordingly, by providing an element isolation region STI below a region between the crack stoppers KS1 to KS4, the semiconductor memory device 1 according to the first embodiment is capable of guiding a crack to a portion between the contact C3V and the contact C3U effectively. That is, the semiconductor memory device 1 according to the first embodiment is capable of guiding a crack in the Z direction further effectively.

Also, in the semiconductor memory device 1r according to the comparative example, the surface protective film 39r may be formed so as to cover a region above a region between the contact C3Vr and the contact C3Ur. On the other hand, in the semiconductor memory device 1 according to the first embodiment, the surface protective film 39 is not provided above the region between the contact C3V and the contact C3U. In the semiconductor memory device 1 according to the first embodiment, since the surface protective film 39 is not provided above the region between the contact C3V and the contact C3U, a crack is likely to be guided to a region above the region between the contact C3V and the contact C3U, compared to the semiconductor memory device 1r. This is because the crack is more likely to pierce to the surface of a portion in which the surface protective film 39 is not provided, compared to a portion in which the surface protective film 39 is provided.

### <2> Modifications of First Embodiment

In the semiconductor memory device 1 according to the first embodiment, an example of providing crack stoppers KS3 and KS4 between the crack stoppers KS1 and KS2 has been described. In other words, an example has been described in which the semiconductor memory device 1 includes two structures each corresponding to the crack stopper KS3 or KS4 provided between the crack stoppers KS1 and KS2. However, the number of structures included in the semiconductor memory device 1 and corresponding to the crack stopper KS3 or KS4 may be designed to be a given number. That is, the number of structures included in the semiconductor memory device 1 and corresponding to the crack stopper KS3 or KS4 may be one, four, or zero. If the number of structures included in the semiconductor memory device 1 and corresponding to the crack stopper KS3 or KS4 is large, the crack generated in the semiconductor substrate 20 can be guided in the Z direction effectively. In order to effectively guide a crack, each structure corresponding to the crack stopper KS3 or KS4 is not positioned below a region between the contacts C3V and C3U.

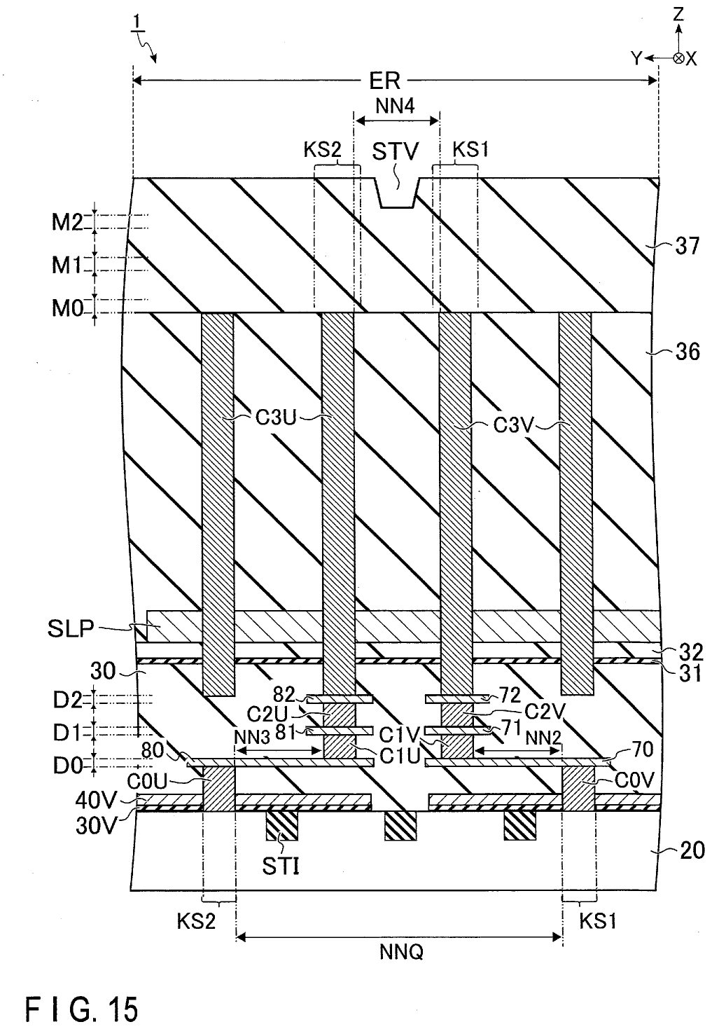

A structure of the end region ER including the crack stoppers KS1 and KS2 in the semiconductor memory device 1 according to the first embodiment is not limited to the above-described structure. FIG. 15 shows an example of a cross-sectional structure of the semiconductor memory device 1 prior to dicing, for example, according to a first modification of the first embodiment.

As shown in FIG. 15, in the semiconductor memory device 1 according to the first modification, a plurality of structures each corresponding to a part of the crack stopper KS1, for example, may be provided. For example, a plurality of contacts C3V may be provided as such structures each corresponding to a part of the crack stopper KS1. Additional contacts C3V other than the first contact C3V are provided in a region closer to the core region CR than the first contact C3V. With a plurality of contacts C3V, the semiconductor memory device 1 according to the first modification is capable of guiding, in the Z direction, a crack that has propagated with a deviation to a region closer to the core region CR than the crack stopper KS1.

Similarly, in the semiconductor memory device 1 according to the first modification, a plurality of structures each corresponding to part of the crack stopper KS2 may be provided. For example, a plurality of contacts C3U may be provided as such structures each corresponding to part of the crack stopper KS2. Additional contacts C3U other than the first contact C3U are provided in a region further distanced from the core region CR than the first contact C3U. With a plurality of contacts C3U, the semiconductor memory device 1 according to the first modification is capable of guiding, in the Z direction, a crack that has propagated with a deviation to a region further distanced from the core region CR than the crack stopper KS2.

Moreover, by providing a plurality of contacts C3V and/or C3U, the semiconductor memory device 1 according to the first modification is capable of compensating for an undesirability due to variations caused in manufacturing. That is, by providing the contact C3V and/or C3U outside the crack stoppers KS1 and KS2, the contacts C3V and C3U at the central side can be formed as per a designed shape without incurring variations caused in manufacturing, and a crack can be guided in the Z direction more reliably with the crack stoppers KS1 and KS2.

Also, as shown in FIG. 15, in the semiconductor memory device 1 according to the first modification, the crack stopper KS1 may have a distance NN2 between the contact C0V and the contact C1V. That is, in the semiconductor memory device 1 according to the first modification, the crack stopper KS1 may have a structure as will be detailed below.

The conductive layer 70 provided above the contact C0V is formed to have a greater width in an XY planar view than the conductive layers 71 and 72, stretching out in a direction approaching the core region CR. The conductive layer 71 is provided on the conductive layer 70 with the contact C1V interposed therebetween. The conductive layer 72 is provided on the conductive layer 71 with the contact C2V interposed therebetween. The contact C3V is provided on the conductive layer 72. The positions at which the contacts C1V, C2V, and C3V are provided are further distanced from the core region CR than the positions at which the contact C0V is provided.

Similarly, in the semiconductor memory device 1 according to the first modification, the crack stopper KS2 may have a distance NN3 between the contact C0U and the contact C1U. That is, in the semiconductor memory device 1 according to the first modification, the crack stopper KS2 may have a structure as will be detailed below.

The conductive layer 80 provided above the contact C0U is formed to have a greater width in an XY planar view than the conductive layers 81 and 82, stretching out in a direction away from the core region CR. The conductive layer 81 is provided on the conductive layer 80 with the contact C1U interposed therebetween. The conductive layer 82 is provided on the conductive layer 81 with the contact C2U interposed therebetween. The contact C3U is provided on the conductive layer 82. The positions at which the contacts C1U, C2U, and C3U are provided are closer to the core region CR than the position at which the contact C0U is provided.

Furthermore, the end region ER in the semiconductor memory device 1 according to the first modification of the first embodiment may have a structure as will be described below in the interior of the insulating layer 30. For example, the insulating layer 30 of the end region ER may include a conductive layer 40 and a gate insulating film, similarly to the insulating layer 30 of the core region CR; however, illustration of such a configuration is omitted in FIG. 9. The conductive layer 40 and the gate insulating film in the end region ER may be respectively referred to as a “conductive layer 40V” and a “gate insulating film 30V” for distinction from the conductive layer 40 and the gate insulating film of the core region CR.

As shown in FIG. 15, the conductive layer 40V is provided on the semiconductor substrate 20 with the gate insulating film 30V interposed therebetween, similarly to the conductive layer 40. The conductive layer 40V is provided above not the entire surface of but a partial surface of the semiconductor substrate 20. The conductive layer 40V is not provided below the region between the contact C3V and the contact C3U. In other words, a region above a region in which the conductive layer 40V is not provided includes the region between the contact C3V and the contact C3U. The conductive layer 40V includes a gap below the region between the contact C3V and the contact C3U. In the region in which the conductive layer 40V is not provided, silicon oxide, for example, is buried.

In an unillustrated region, the region in which the conductive layer 40V is not provided may include a portion extending in the Y direction. The region in which the conductive layer 40V is not provided may include a portion extending in the X direction. Thereby, the region in which the conductive layer 40V is not provided is provided, for example, in a discrete manner along a rectangular toroidal shape in an XY planar view. Such a region in which the conductive layer 40V is not provided surrounds the core region CR in a discrete rectangular toroidal shape.

In this manner, by providing a gap in the conductive layer 40V, the semiconductor memory device 1 according to the first modification of the first embodiment is capable of guiding a crack to a portion in which the gap is provided. In propagation of the crack generated in the semiconductor substrate 20 to the insulating layer 30, the crack is likely to be guided to a region in which the conductive layer 40V is not provided (a region in which a gap is provided), rather than a region in which the conductive layer 40V is provided. Accordingly, by not providing the conductive layer 40V below the region between the contact C3V and the contact C3U, the semiconductor memory device 1 according to the first modification of the first embodiment is capable of guiding the crack effectively to a region between the contact C3V and the contact C3U. That is, the semiconductor memory device 1 according to the first modification of the first embodiment is capable of guiding a crack in the Z direction further effectively.

Furthermore, in the semiconductor memory device 1 according to the first modification of the first embodiment, the end region ER may include a trench STV in an upper surface of the insulating layer 37 exposed from a surface protective film 39 (unillustrated). That is, the insulating layer 37 may include a trench STV above the region between the contact C3V and the contact C3U, as shown in FIG. 15. In other words, a height of a portion of the insulating layer 37 in which the trench STV is formed in the +Z direction is smaller than a height of the other portion of the insulating layer 37 in the +Z direction.

By providing a trench STV in the insulating layer 37, the semiconductor memory device 1 according to the first modification of the first embodiment is capable of guiding a crack to a portion in which the trench STV is provided. The crack that has propagated to the insulating layer 37 is likely to be guided to a portion of the insulating layer 37 in which the trench STV is provided, rather than a portion in which the trench STV is not provided. Accordingly, by providing the trench STV above the region between the contact C3V and the contact C3U, the semiconductor memory device 1 according to the first modification of the first embodiment is capable of guiding a crack in the Z direction further effectively.

In an unillustrated region, the trench STV includes a portion extending in the Y direction. The trench STV also includes a portion extending in the X direction. Thereby, the trench STV is provided, for example, in a rectangular toroidal shape and surrounds the core region CR in an XY planar view. Alternatively, the trench STV may be provided, for example, in a discrete manner along a rectangular toroidal shape in an XY planar view. In this case, the trench STV surrounds the core region CR in a discrete rectangular toroidal shape in an XY planar view.

In the first embodiment described above, an example has been described in which a spacer SP is provided on side surfaces of the contacts C3U, C3V, and C3W; however, the structures of the sealing members ESn and ESp and the crack stoppers KS1 and KS2 are not limited thereto. The spacer SP may or may not be provided on side surfaces of the contacts C3U, C3V, and C3W.

For example, a contact provided in the core region CR includes a spacer SP on a side surface to provide insulation from the layer stack SLP. For convenience in manufacturing, the contacts C3U, C3V, and C3W are formed in the same process as the contacts provided in the core region CR, and may have a spacer SP on the side surface. On the other hand, FIG. 15 shows an example in which the contacts C3U and C3V are formed independently from the contacts in the core region CR, and a spacer SP is not provided on a side surface of each of the contacts C3U and C3V.

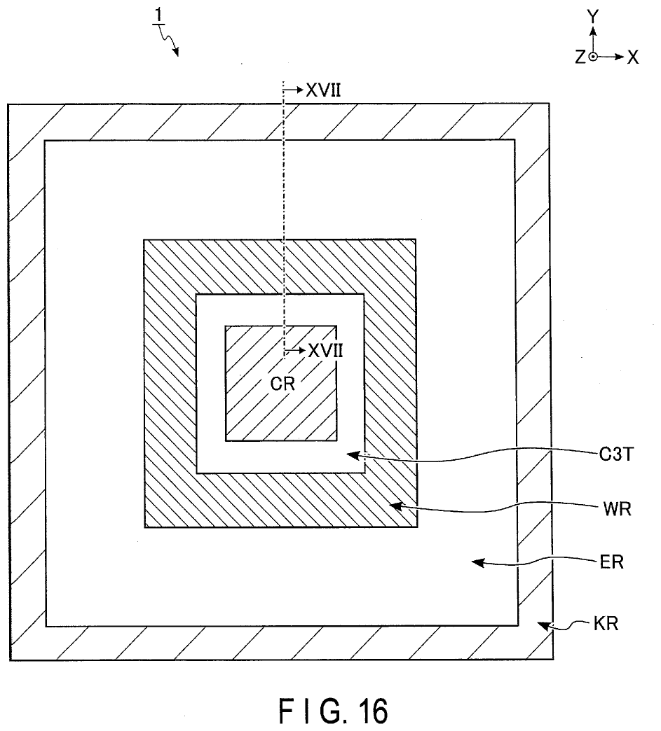

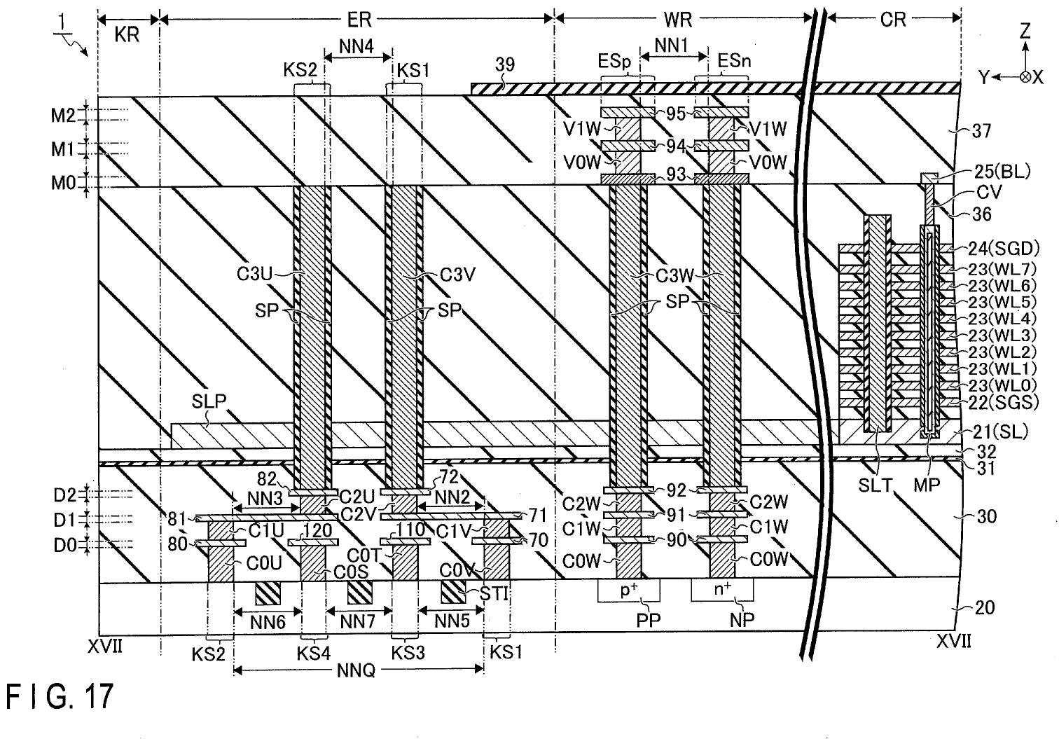

In the semiconductor memory device 1 according to a second modification of the first embodiment, blade dicing may be used in dicing. FIGS. 16 and 17 show a planar layout and a cross-sectional structure, respectively, of the semiconductor memory device 1 according to the second modification of the first embodiment. FIG. 17 is a cross-sectional view taken along line XVII-XVII of FIG. 16. FIGS. 16 and 17 show a planar layout and a cross-sectional structure, respectively, of the semiconductor memory device 1 in the case of using blade dicing. FIG. 16 shows a region including the region shown in FIG. 3. FIG. 17 shows a region including the region shown in FIG. 9. In the region shown in FIG. 17, a part of the region shown in FIG. 12 is included.

Similarly to stealth dicing, the semiconductor memory device 1 according to the second modification is manufactured by blade-dicing the semiconductor memory device 1 prior to dicing, as described with reference to FIGS. 10 to 12. In blade dicing, the semiconductor memory device 1 is cut, for example, in the kerf region KR described with reference to FIGS. 10 to 12.

In blade dicing, dicing is performed from an upper part with a blade. Accordingly, a crack propagates downward from an upper part of the semiconductor memory device 1 as a starting point in the Z axis, and divides the wafer. It is ideal that the crack pass through the kerf region KR.

At this time, in the semiconductor memory device 1 according to the second modification, the kerf region KR becomes the outermost periphery of the semiconductor memory device 1, as shown in FIGS. 16 and 17. That is, the semiconductor memory device 1 according to the second modification includes crack stoppers KS1 to KS4.

The crack stoppers KS1 to KS4 exhibit advantageous effects similar to those of the first embodiment even if blade dicing is performed. Even in the case where, for example, dicing is performed from an upper part of the kerf region KR, such as blade dicing, a crack may occur in the vicinity of the semiconductor substrate 20 due to, for example, a stress, etc. Upon occurrence of a crack in the vicinity of the semiconductor substrate 20, the crack stoppers KS1 and KS2 may suppress the generated crack from damaging the core region CR.

In this manner, the semiconductor memory device 1 according to the second modification may include a crack stopper KS2 or KS4 or a kerf region KR, depending on the dicing method or the propagation direction of the crack. In this case, in the semiconductor memory device 1 according to the second modification, the kerf region KR becomes the outermost periphery of the semiconductor memory device 1, as described with reference to FIGS. 16 and 17. Alternatively, in the semiconductor memory device 1 according to the second modification, the end region ER may become the outermost periphery of the semiconductor memory device 1.

### <3> Second Embodiment

Hereinafter, a description will be given of a semiconductor memory device 1 according to a second embodiment. Hereinafter, the semiconductor memory device 1 according to the second embodiment may be referred to as a “semiconductor memory device 1b”. Also, “sealing members ESn and ESp” in the second embodiment may be respectively referred to as “sealing members ESnb and ESpb”. Also, the “crack stoppers KS1 to KS4” in the second embodiment may be respectively referred to as “crack stoppers KS1b to KS4b”.

The semiconductor memory device 1b differs from the semiconductor memory device 1 according to the first embodiment (FIG. 9) mainly in terms of the structure above the interconnect layer D2. The semiconductor memory device 1b is manufactured by a method in which a structure corresponding to the structure from the semiconductor substrate 20 to the insulating layer 30 and a structure above the insulating layer 30 in the Z axis are separately formed, and the formed structures are bonded. Even with a structure using such a manufacturing method, the structure of the crack stopper described in the first embodiment is applicable. That is, similarly to the first embodiment, the distance between the crack stopper KS1b and the crack stopper KS2b of the semiconductor memory device 1b according to the second embodiment is greater in a lower portion and is smaller in an upper portion as viewed in the Z axis. Hereinafter, characteristics that are newly added with respect to the first embodiment will be mainly described.

### <3-1> Configuration (Structure)

Hereinafter, a description will be given mainly of a structure above the interconnect layer D2 of the semiconductor memory device 1b according to the second embodiment.

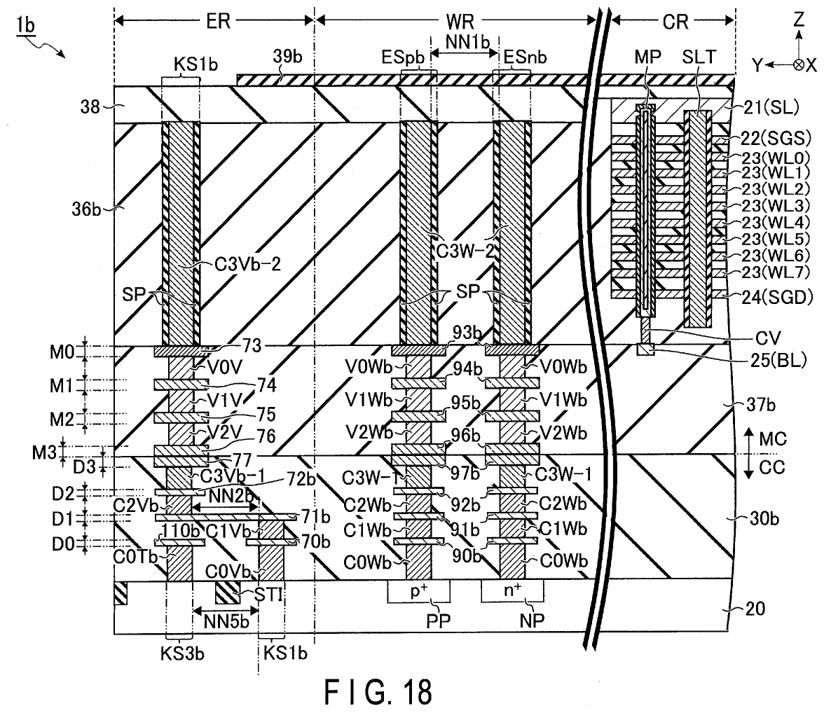

FIG. 18 shows an example of a cross-sectional structure of the semiconductor memory device 1b according to the second embodiment. FIG. 18 shows a cross section of the same region as that in FIG. 9 according to the first embodiment. In the semiconductor memory device 1b, a structure corresponding to the structure from the semiconductor substrate 20 to the insulating layer 30 in the Z direction and a structure corresponding to the insulating layer 37 and the portion above the insulating layers 37 in the Z direction are separately formed. A structure corresponding to a structure from the semiconductor substrate 20 to the insulating layer 30 of the semiconductor memory device 1 in the Z direction may be referred to as a “CMOS chip CC”. A structure corresponding to the insulating layer 37 and a portion above the insulating layer 37 in the Z axis may be hereinafter referred to as a “memory chip MC”.

In the second embodiment, portions corresponding to the insulating layers 30, 36, and 37 and the surface protective film 39 of the first embodiment may be hereinafter respectively referred to as “insulating layers 30b, 36b, and 37b”, and “surface protective film 39b”. The semiconductor memory device 1b has a structure in which a surface opposed to the CMOS chip CC of the memory chip MC (a bottom surface of the insulating layer 37b) and a surface opposed to the memory chip MC of the CMOS chip CC (an upper surface of the insulating layer 30b) are bonded. The bottom surface of the insulating layer 37b corresponds to, for example, an upper surface of the insulating layer 37 of the first embodiment.

As shown in FIG. 18, the semiconductor memory device 1b includes a memory chip MC, a CMOS chip CC, an insulating layer 38, and a surface protective film 39b. The memory chip MC includes insulating layers 36b and 37b. The CMOS chip CC includes a semiconductor substrate 20 and an insulating layer 30b.

That is, the insulating layer 30b is provided on the semiconductor substrate 20. The insulating layer 37b is provided on the insulating layer 30b. The insulating layer 36b is provided on the insulating layer 37b. The insulating layer 38 is provided on the insulating layer 36b. In other words, the insulating layer 38 is provided on the memory chip MC. The height of the upper surface of the insulating layer 36b may vary, for example, according to the region. In accordance therewith, the thickness of the insulating layer 38 may vary, for example, according to the region. The surface protective film 39b is provided above the insulating layer 38. The surface protective film 39b is provided in a region that is inside of an upper portion of an upper end of the crack stopper KS1b and that is other than a region in which a terminal for coupling with the exterior is provided, similarly to the surface protective film 39 of the first embodiment.

Since the structure of the semiconductor substrate 20 and a portion of the insulating layer 30b at the height of or below the interconnect layer D2 is similar to the structure of the semiconductor substrate 20 and a portion of the insulating layer 30 at the height of or below the interconnect layer D2 according to the first embodiment, a detailed description thereof will be omitted.

A layer including an upper surface of the insulating layer 30b (which is positioned above the interconnect layer D2) may be referred to as a “bonded layer D3”. The insulating layer 30b includes a plurality of bonding pads in the bonded layer D3. A bonding pad may be referred to as a “joint metal”.

Since the structure of the interconnect layers M0 to M2 in the interior of the insulating layer 37b is similar to the structure in which the structure of the interconnect layers M0 to M2 in the interior of the insulating layer 37 according to the first embodiment is vertically inverted in the Z axis, a detailed description thereof will be omitted.

A layer including the bottom surface of the insulating layer 37b (which is positioned below the interconnect layer M2) may be referred to as a “bonded layer M3”. The insulating layer 37b includes a plurality of bonding pads in the bonded layer D3. The bonding pads in the bonded layer M3 are arranged to respectively overlap the bonding pads in the bonded layer D3.

Since the structure of the interior of the insulating layer 36b is similar to the structure in which the structure of the interior of the insulating layer 36 according to the first embodiment is vertically inverted in the Z axis, a detailed description thereof will be omitted. The insulating layer 36b may include a stacked structure used for formation of the source line SL in the wall region WR and the end region ER, similarly to the first embodiment; however, illustration of such a configuration is omitted.

Of the bonding pads provided in the semiconductor memory device 1b, two bonding pads that are opposed to each other between the insulating layer 37b and the insulating layer 30b (i.e., between the memory chip MC and the CMOS chip CC) are bonded. Thereby, the circuitry in the memory chip MC and the circuitry in the CMOS chip CC are electrically coupled. Two bonding pads that are opposed to each other between the memory chip MC and the CMOS chip CC may be either bordered or integrated. For example, the bonding pads in the core region CR are coupled with bit lines BL associated therewith; however, illustration of such a configuration is omitted.

Each of the sealing members ESnb and ESpb extends in the Z direction, similarly to the sealing members ESn and ESp of the first embodiment. The sealing member ESpb is further distanced from the core region CR than the sealing member ESnb in an XY planar view. Each of the sealing members ESnb and ESpb splits the insulating layers 30b, 37b, and 36b. Each of the sealing members ESn and ESp includes conductive layers 90b to 97b, and contacts C0Wb to C2Wb, C3W-1, C3W-2, and V0Wb to V2Wb.

A structure of the semiconductor substrate 20 and a portion of the insulating layer 30b at the height of or below the interconnect layer D2 in the semiconductor memory device 1b is similar to the structure of the semiconductor substrate 20 and a portion of the insulating layer 30 at the height of or below the interconnect layer D2 in the semiconductor memory device 1 according to the first embodiment. The conductive layers 90b to 92b and the contacts C0Wb to C2Wb in the sealing members ESnb and ESpb are respectively similar to the conductive layers 90 to 92 and the contacts COW to C2W in the sealing members ESn and ESp. Accordingly, the description of the conductive layers 90 to 92 and the contacts COW to C2W is applicable to features other than the features to be described below of the conductive layers 90b to 92b and the contacts C0Wb to C2Wb, and a detailed description thereof will be omitted.

In the sealing members ESnb and ESpb, the conductive layer 97b is provided on the conductive layer 92b with the contact C3W-1 interposed therebetween. The conductive layer 97b is used as a bonding pad. The conductive layer 96b is provided on the conductive layer 97b. The conductive layer 96b abuts on an interface of the CMOS chip CC, and is used as a bonding pad. The conductive layer 95b is provided on the conductive layer 96b with the contact V2Wb interposed therebetween. The conductive layer 94b is provided on the conductive layer 95b with the contact V1Wb interposed therebetween. The conductive layer 93b is provided on the conductive layer 94b with the contact V0Wb interposed therebetween. The contact C3W-2 is provided on the conductive layer 93b. In this manner, the sealing members ESnb and ESpb extend along the Z axis. The conductive layer 96b may be provided not directly above the conductive layer 97b, but be provided so as to be displaced in the Y direction and/or X direction. Such a case will be described in a modification.

The conductive layers 97b, 96b, 95b, 94b, and 93b are respectively included in the bonded layers D3 and M3 and the interconnect layers M2, M1, and M0. A set of the contacts V2Wb, V1Wb, and V0Wb and the conductive layers 96b, 95b, 94b, and 93b splits the insulating layer 37b. Also, the contact C3W-2 splits the insulating layer 36b. An upper surface of the contact C3W-2 reaches at least a height of a lower surface of the conductive layer 21. A spacer SP is provided on a side surface of the contact C3W-2. The spacer SP may or may not be provided.

In an unillustrated region, a set of the conductive layers 90b to 97b, the contacts C0Wb to C2Wb, C3W-1, C3W-2, and V0Wb to V2Wb include a portion extending in the Y direction. Also, the set of the conductive layers 90b to 97b and the contacts C0Wb to C2Wb, C3W-1, C3W-2, and V0Wb to V2Wb also include a portion extending in the X direction. Thereby, the set of the conductive layers 90b to 97b and the contacts C0Wb to C2Wb, C3W-1, C3W-2, and V0Wb to V2Wb is provided, for example, in a rectangular toroidal shape and surrounds the core region CR. The conductive layers 93b to 95b and the contacts V0Wb to V2Wb, C3W-1, and C3W-2 contain, for example, a metal such as tungsten and copper. The conductive layers 96b and 97b contain, for example, copper. The spacer SP is, for example, a silicon oxide film. Each of the sealing members ESnb and ESpb may be regarded as a wall between the core region CR and the outer edge of the semiconductor memory device 1b.

The contacts C3W-2 of the sealing members ESnb and ESpb are distanced from each other by, for example, a distance NN1b in an XY planar view. In other words, in FIG. 18, namely, in a YZ planar view, the contacts C3W-2 of the sealing members ESnb and ESpb are distanced from each other by a distance NN1b in the Y direction.

The crack stopper KS1b has a bent structure, while extending in the Z direction, similarly to the crack stoppers KS1 and KS2 of the first embodiment. The crack stopper KS1b splits the insulating layers 30b, 37b, and 36b.

The crack stopper KS1b includes conductive layers 70b to 72b and 73 to 77 and contacts C0Vb to C2Vb, C3Vb-1, C3Vb-2, and V0V to V2V.

A structure of the semiconductor substrate 20 and a portion of the insulating layer 30b at the height of or below the interconnect layer D2 in the semiconductor memory device 1b is similar to the structure of the semiconductor substrate 20 and a portion of the insulating layer 30 at the height of or below the interconnect layer D2 in the semiconductor memory device 1 according to the first embodiment. The conductive layers 70b to 72b and the contacts C0Vb to C2Vb in the crack stopper KS1b are respectively similar to the conductive layers 70 to 72 and the contacts C0V to C2V in the crack stopper KS1 of the first embodiment. Accordingly, the description of the conductive layers 70 to 72 and the contacts C0V to C2V is applicable to features other than the features to be described below of the conductive layers 70b to 72b and the contacts C0Vb to C2Vb, and a detailed description thereof will be omitted. Herein, the distance NN2 of the second embodiment may be referred to as a “distance NN2b”, to be distinguished from the distance NN2 of the first embodiment.

In the crack stopper KS1b, a conductive layer 77 is provided on the conductive layer 72b with the contact C3Vb-1 interposed therebetween. The conductive layer 77 is used as a bonding pad. The conductive layer 76 is provided on the conductive layer 77. The conductive layer 76 abuts on an interface of the CMOS chip CC, and is used as a bonding pad. The conductive layer 75 is provided on the conductive layer 76 with the contact V2V interposed therebetween. The conductive layer 74 is provided on the conductive layer 75 with the contact V1V interposed therebetween. The conductive layer 73 is provided on the conductive layer 74 with the contact V0V interposed therebetween. The contact C3Vb-2 is provided on the conductive layer 73. In this manner, the crack stopper KS1b bends in the insulating layer 30b, and extends in the Z direction in the other portions.

The conductive layers 77, 76, 75, 74, and 73 are respectively included in the bonded layers D3 and M3 and the interconnect layers M2, M1, and M0. A set of the contacts V2V, V1V, and V0V and the conductive layers 76, 75, 74, and 73 splits the insulating layer 37b. Also, the contact C3Vb-2 splits the insulating layer 36b. An upper surface of the contact C3Vb-2 reaches at least a height of a lower surface of the conductive layer 21. A spacer SP is provided on a side surface of the contact C3Vb-2. The spacer SP may or may not be provided.

In an unillustrated region, a set of the conductive layers 70b to 72b and 73 to 77 and the contacts C0Vb to C2Vb, C3Vb-1, C3Vb-2, and V0V to V2V includes a portion extending in the Y direction. Also, the set of the conductive layers 70b to 72b and 73 to 77 and the contacts C0Vb to C2Vb, C3Vb-1, C3Vb-2, and V0V to V2V also includes a portion extending in the X direction. Thereby, the set of the conductive layers 70b to 72b and 73 to 77 and the contacts C0Vb to C2Vb, C3Vb-1, C3Vb-2, and V0V to V2V is provided, for example, in a rectangular toroidal shape and surrounds the core region CR in an XY planar view. Each of the conductive layers 73 to 75 and the contacts V0V to V2V, C3Vb-1, and C3Vb-2 contains, for example, a metal such as tungsten and copper. The conductive layers 76 and 77 contain, for example, copper. The crack stopper KS1b includes, for example, a tungsten-containing structure in each of a layer above the conductive layer 76 and a layer below the conductive layer 77. The spacer SP is, for example, a silicon oxide film. The crack stopper KS1b may be regarded as a wall between the core region CR and the kerf region KR.

Similarly to the semiconductor memory device 1, the semiconductor memory device 1b may include a crack stopper KS3b in the end region ER. The crack stopper KS3b extends in the Z direction. The crack stopper KS3b splits, for example, a part of the insulating layer 30b.

The crack stopper KS3b includes a conductive layer 110h and a contact C0Tb. The conductive layer 110b and the contact C0Tb in the crack stopper KS3b are similar to the conductive layer 110 and the contact COT, respectively, in the crack stopper KS3 of the first embodiment. Accordingly, the description of the conductive layer 110 and the contact COT is applicable to the conductive layer 110b and the contacts C0Tb, and a detailed description thereof will be omitted. Herein, the distance NN5 of the second embodiment may be referred to as a “distance NN5b”.

### <3-2> Method of Manufacturing Semiconductor Memory Device 1

Hereinafter, an example of a process relating to dicing, in the process of manufacturing the semiconductor memory device 1b according to the second embodiment, will be described. The process to be described below is based on an example in which stealth dicing is used, similarly to the first embodiment.

A planar layout of the semiconductor memory device 1 prior to dicing is similar to that in FIGS. 10 and 11 according to the first embodiment, and a description thereof will be omitted.

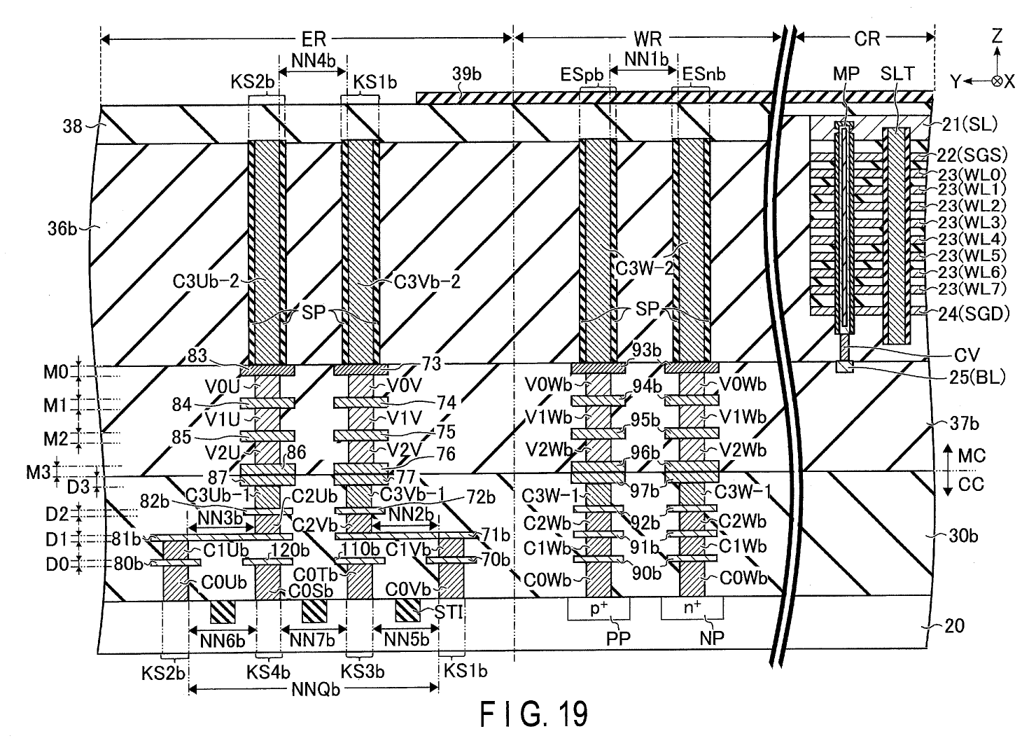

A structure of the semiconductor memory device 1b prior to dicing will be described with reference to FIG. 19. FIG. 19 shows a cross-sectional structure of the semiconductor memory device 1b prior to dicing. As shown in FIG. 19, a structure closer to the core region CR than the crack stoppers KS1b and KS3b is similar to that described with reference to FIG. 18, and a description thereof will be omitted. The semiconductor memory device 1b during manufacturing further includes a crack stopper KS2b in the end region ER. The semiconductor memory device 1b during manufacturing may further include a crack stopper KS4b in the end region ER.

Since the structure of the semiconductor substrate 20 and a portion of the insulating layer 30b at the height of or below the interconnect layer D2 is similar to the structure of the semiconductor substrate 20 and a portion of the insulating layer 30 at the height of or below the interconnect layer D2 according to the first embodiment, a detailed description thereof will be omitted.

The crack stopper KS2b has a bent structure, while extending in the Z direction, similarly to the crack stopper KS2 of the first embodiment. The crack stopper KS2b is further distanced from the core region CR than the crack stopper KS1b in an XY planar view. The crack stopper KS2b splits the insulating layers 30b, 37b, and 36b.

The crack stopper KS2b includes conductive layers 80b to 82b and 83 to 87 and contacts C0Ub to C2Ub, C3Ub-1, C3Ub-2, and VOU to V2U.

The conductive layers 80b to 82b and the contacts C0Ub to C2Ub in the crack stopper KS2b are respectively similar to the conductive layers 80 to 82 and the contacts C0U to C2U in the crack stopper KS2 of the first embodiment. Accordingly, the description of the conductive layers 80 to 82 and the contacts C0U to C2U is applicable to features other than the features to be described below of the conductive layers 80b to 82b and the contacts C0Ub to C2Ub, and a detailed description thereof will be omitted. Herein, the distances NN3 and NNQ in the second embodiment may be respectively referred to as a “distance NN3b” and a “distance NNQb”.

In the crack stopper KS2b, a conductive layer 87 is provided on the conductive layer 82b with the contact C3Ub-1 interposed therebetween. The conductive layer 87 is used as a bonding pad. The conductive layer 86 is provided on the conductive layer 87. The conductive layer 86 abuts on an interface of the CMOS chip CC, and is used as a bonding pad. The conductive layer 85 is provided on the conductive layer 86 with the contact V2U interposed therebetween. The conductive layer 84 is provided on the conductive layer 85 with the contact V1U interposed therebetween. The conductive layer 83 is provided on the conductive layer 84 with the contact VOU interposed therebetween. The contact C3Ub-2 is provided on the conductive layer 83.

The position at which the contact C3Ub-2 is provided is further distanced from the core region CR than the position at which the contact C3Vb-2 is provided. The contacts C3Ub-2 and C3Vb-2 are distanced from each other by, for example, a distance NN4b. In other words, in FIG. 19, the contact C3Ub-2 is distanced from the contact C3Vb-2 by a distance NN4b in the +Y direction. The distance NN4b may be substantially identical in length to the distance NN1b, the distance NN2b, and/or the distance NN5b. In this manner, the crack stopper KS2b bends in the insulating layer 30b, and extends in the Z direction in the other portions.

The conductive layers 87, 86, 85, 84, and 83 are respectively included in the bonded layers D3 and M3 and the interconnect layers M2, M1, and M0. A set of the contacts V2U, V1U, and VOU and the conductive layers 86, 85, 84, and 83 splits the insulating layer 37b. Also, the contact C3Ub-2 splits the insulating layer 36b. An upper surface of the contact C3Ub-2 reaches at least a height of a lower surface of the conductive layer 21. A spacer SP is provided on a side surface of the contact C3Ub-2. The spacer SP may or may not be provided.

In an unillustrated region, a set of the conductive layers 80b to 82b and 83 to 87 and the contacts C0Ub to C2Ub, C3Ub-1, C3Ub-2, and VOU to V2U includes a portion extending in the Y direction. Also, the set of the conductive layers 80b to 82b and 83 to 87 and the contacts C0Ub to C2Ub, C3Ub-1, C3Vb-2, and VOU to V2U also includes a portion extending in the X direction. Thereby, the set of the conductive layers 80h to 82b and 83 to 87 and the contacts C0Ub to C2Ub, C3Ub-1, C3Ub-2, and VOU to V2U is provided, for example, in a rectangular toroidal shape and surrounds the core region CR in an XY planar view. Each of the conductive layers 83 to 85 and the contacts VOU to V2U, C3Ub-1, and C3Ub-2 contains, for example, a metal such as tungsten and copper. The conductive layers 86 and 87 contain, for example, copper. The crack stopper KS2b includes, for example, a tungsten-containing structure in each of a layer above the conductive layer 86 and a layer below the conductive layer 87. The spacer SP is, for example, a silicon oxide film. The crack stopper KS2b may be regarded as a wall between the core region CR and the kerf region KR.

The distance NNQb between the contact C0Vb and the contact C0Ub is greater than the distance NN4b between the contact C3Vb-2 and the contact C3Ub-2. That is, a distance between the crack stopper KS1b and the crack stopper KS2b is greater in a lower portion and is smaller in an upper portion as viewed in the Z axis.

The crack stopper KS4b extends in the Z direction. The crack stopper KS4b splits, for example, a part of the insulating layer 30b. The crack stopper KS4b is positioned between the crack stopper KS2b and the crack stopper KS3b in an XY planar view.

The crack stopper KS4b includes a conductive layer 120b and a contact C0Sb. The conductive layer 120b and the contact C0Sb in the crack stopper KS4b are similar to the conductive layer 120 and the contact COS, respectively, in the crack stopper KS4 of the first embodiment. Accordingly, the description of the conductive layer 120 and the contact COS is applicable to the conductive layer 120b and the contacts C0Sb, and a detailed description thereof will be omitted. Herein, the distances NN6 and NN7 in the second embodiment may be respectively referred to as a “distance NN6b” and a “distance NN7b”.

By dicing the semiconductor memory device 1b prior to dicing, as described with reference to FIG. 19, the semiconductor memory device 1b is manufactured. Hereinafter, an example of a stealth dicing process in the semiconductor memory device 1b will be described.

First, a laser used for dicing is applied to a portion of the semiconductor substrate 20 below the region between the contact C3Vb-2 and the contact C3Ub-2. The portion to which a laser is applied becomes a starting point of stealth dicing.

Subsequently, a tensile stress, etc. is applied to a wafer including the semiconductor memory device 1b, generating a crack in the vicinity of the portion to which the laser is applied. The generated crack propagates upward in the Z axis, and divides the insulating layers 30b, 37b, 36b, and 38, thus dividing the wafer. A portion of the divided wafer that includes the core region CR becomes the semiconductor memory device 1b.

It is ideal that a crack pass through the region between the contact C3Vb-2 and the contact C3Ub-2. At this time, the semiconductor memory device 1b has a structure described with reference to FIG. 18. That is, in the case of ideal propagation of a crack, the semiconductor memory device 1b includes crack stoppers KS1b and KS3b, and includes neither crack stoppers KS2b and KS4b nor a kerf region KR.

The semiconductor memory device 1b may include a crack stopper KS2b or KS4b or a kerf region KR, depending on the dicing method or the propagation direction of the crack.

### <3-3> Advantages (Effects) of Second Embodiment

With the above-described semiconductor memory device 1b according to the second embodiment, it is possible to improve a yield of the semiconductor memory device 1b, similarly to the first embodiment.

Similarly to the first embodiment, there is a demand for using stealth dicing, as well as blade dicing, in dicing of the semiconductor memory device 1b with a bonded structure. Accordingly, a crack stopper capable of effectively suppressing damage to the core region CR caused by the crack is desired.

Similarly to the first embodiment, in the semiconductor memory device 1b according to the second embodiment, the shape of the crack stoppers KS1b and KS2b is designed to effectively guide a crack. That is, in the semiconductor memory device 1b, a distance NNQb between the contact C0Vb and the contact C0Ub is greater than a distance NN4b between the contact C3Vb-2 and the contact C3Ub-2. Also, a distance between the crack stopper KS1b and the crack stopper KS2b is greater in a lower portion and is smaller in an upper portion as viewed in the Z axis.

Accordingly, the crack stoppers KS1b and KS2b in the semiconductor memory device 1b according to the second embodiment are capable of guiding a crack in the Z direction effectively, compared to the case where, for example, the crack stoppers KS1r and KS2r do not have a bent shape as in the semiconductor memory device 1r according to the comparative example of the first embodiment. That is, similarly to the first embodiment, the crack stoppers KS1b and KS2b are capable of suppressing damage to the core region CR caused by the crack effectively, compared to the crack stoppers KS1b and KS2b which do not have a bent shape.

Moreover, similarly to the first embodiment, the semiconductor memory device 1b according to the second embodiment is capable of guiding a crack in the Z direction simply by including the crack stoppers KS1b and KS2b, but is capable of guiding a crack in the Z direction further effectively by including the crack stoppers KS3b and KS4b.

Furthermore, similarly to the first embodiment, by providing an element isolation region STI below a region between the crack stoppers KS1b to KS4b, the semiconductor memory device 1b according to the second embodiment is capable of guiding a crack to a region between the contact C3Vb-2 and the contact C3Ub-2 effectively. Thereby, the semiconductor memory device 1b according to the second embodiment is capable of guiding a crack in the Z direction further effectively.

Also, similarly to the first embodiment, in the semiconductor memory device 1b according to the second embodiment, since the surface protective film 39b is not provided above the region between the contact C3Vb-2 and the contact C3Ub-2, a crack will likely be guided to a region above the region between the contact C3Vb-2 and the contact C3Ub-2.

### <4> Modification of Second Embodiment

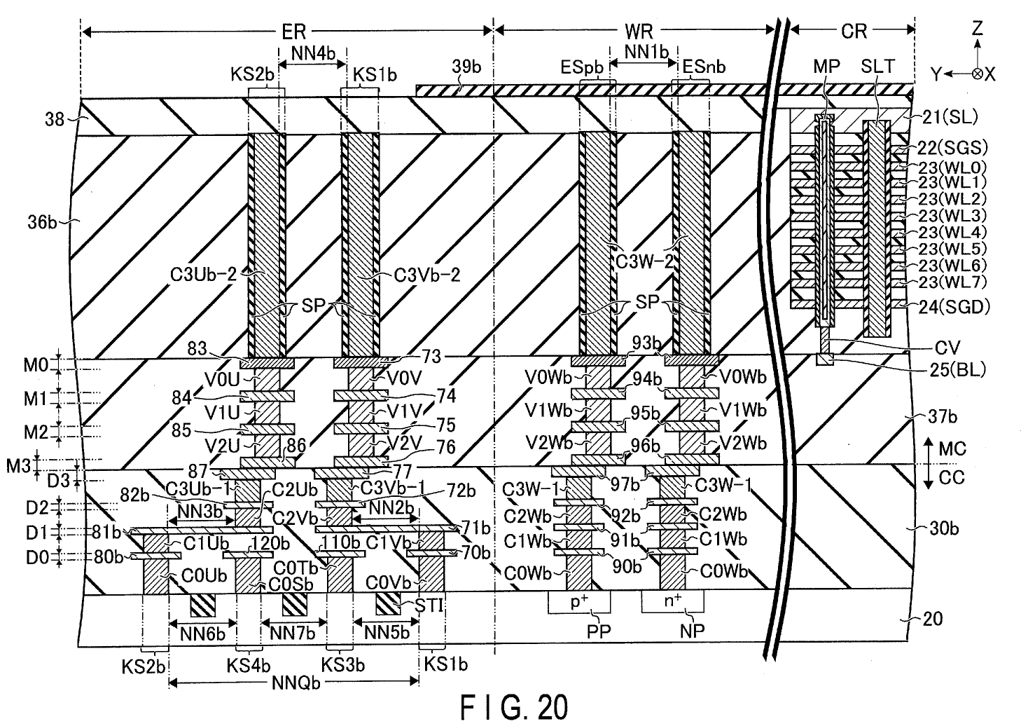

In bonding the memory chip MC and the CMOS chip CC in the semiconductor memory device 1b, the bonding pad of the memory chip MC and the bonding pad of the CMOS chip CC may be bonded so as to be displaced from each other. This case will be described with reference to FIG. 20.

FIG. 20 shows an example of a cross-sectional structure of the semiconductor memory device 1b prior to dicing according to a modification of the second embodiment. FIG. 20 shows the same region as that in FIG. 19.

As shown in FIG. 20, the conductive layers 96b, 76, and 86 in the bonded layer M3 are provided not directly above the conductive layers 97b, 77, and 87 in the bonded layer D3 but are provided so as to be displaced in the −Y direction. Such a structure may occur if, for example, the position of bonding of the memory chip MC to the CMOS chip CC is displaced in the −Y direction.

In the case of a maximum displacement, each of the conductive layers 96b, 76, and 86 includes a portion that overlaps the conductive layers 97b, 77, and 87. That is, the crack stoppers KS1b and KS2b and the sealing members ESnb and ESpb are continuously provided. Even in the case of a maximum displacement, the conductive layers 76 and 86 do not overlap the conductive layers 87 and 77, respectively.

FIG. 20 shows an example in which the memory chip MC is deviated in the −Y direction; however, the same applies to the case of displacement in the +Y direction, the +X direction, and the −X direction. In this case, the conductive layers 96b, 76, and 86 are provided not directly above the conductive layers 97b, 77, and 87, but are provided so as to be displaced in the Y direction and/or the X direction. That is, the conductive layers 96b, 76, and 86 are provided not directly above the conductive layers 97b, 77, and 87, but are provided so as to be displaced in a direction approaching the outermost periphery of the semiconductor substrate 20 from the core region CR or a direction approaching the core region CR from the outermost periphery of the semiconductor substrate 20. In other words, side surfaces of the conductive layer 97b, 77, and 87 may not be positioned on extensions of the side surfaces of the conductive layers 96b, 76, and 86.

Also, upon occurrence of such a displacement, in the crack stopper KS1b, for example, the contacts C3Vb-2 and V0V to V2V are not positioned directly above the contacts C3Vb-1 and C2Vb. Even if the contacts C3Vb-2 and V0V to V2V are not positioned directly above the contacts C3Vb-1 and C2Vb, the crack stopper KS1b is continuously provided, and the conductive layers 76 and 86 do not overlap the conductive layers 87 and 77, respectively. The same applies to the crack stopper KS2b.

Accordingly, even if the memory chip MC and the CMOS chip CC are provided so as to be displaced in the Y direction and/or the X direction, the advantageous effects of the second embodiment are not affected. That is, even if the memory chip MC and the CMOS chip CC are provided so as to be displaced in the Y direction and/or the X direction, the crack stoppers KS1b and KS2b may guide a crack generated in the semiconductor substrate 20 in the Z direction effectively.

Also, in the semiconductor memory device 1b, it is possible to distinguish between a bonding pad and a general interconnect layer. In a bonding process of the memory chip MC and the CMOS chip CC, the conductive layers 96b, 76, and 86 are respectively bonded to the conductive layers 97b, 77, and 87. If, for example, copper is used for the conductive layers 76 and 77, the copper of the conductive layer 76 and the copper of the conductive layer 77 become integral, making it difficult to recognize a boundary therebetween.

Even in such a case, as described with reference to FIG. 20, for example, since the conductive layer 76 and the conductive layer 77 are provided so as to be displaced in the Y direction and/or the X direction, it is possible to recognize that it is a bonded structure. Also, it is possible to recognize, based on the displacement in position of the barrier metal of the copper (generation of a discontinuous portion on a side surface), that it is a bonded structure. The same applies to the set of the conductive layers 96b and 97b and the set of the conductive layers 86 and 87.

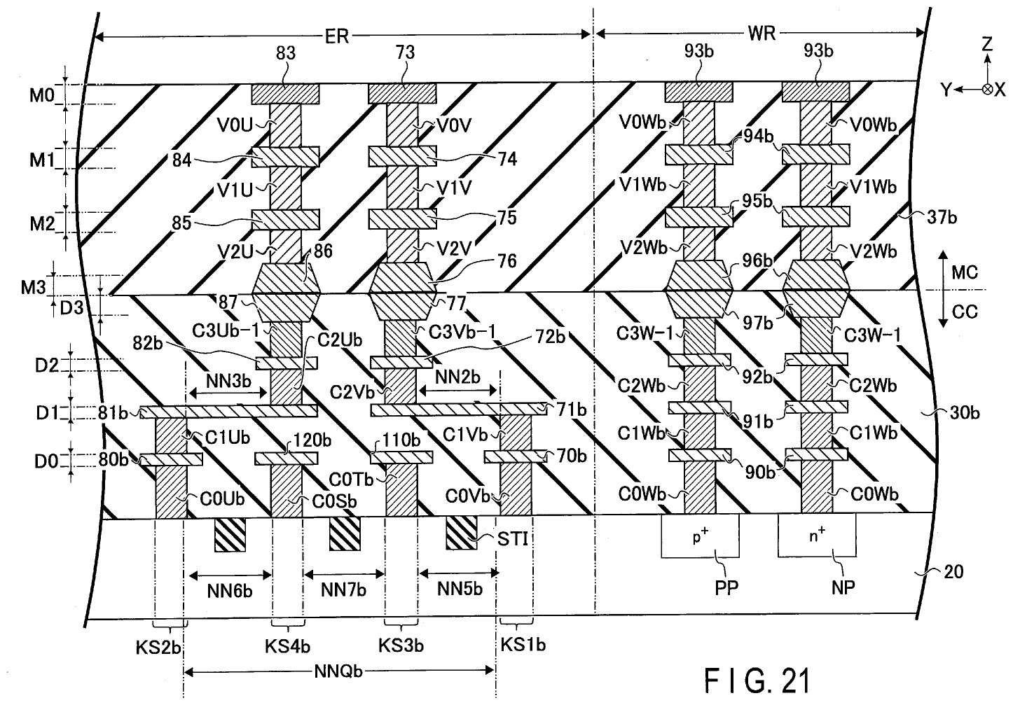

Moreover, in the case of forming the conductive layers 96b, 76, 86, 97b, 77, and 87 by a damascene method, each side surface has a tapered shape. This case will be described with reference to FIG. 21. FIG. 21 shows an example of a cross-sectional structure of the semiconductor memory device 1b prior to dicing according to a modification of the second embodiment. FIG. 21 is a partially enlarged view of the same cross section as that of FIG. 19. As shown in FIG. 21, in the semiconductor memory device 1b according to the modification, for example, inverse-tapered conductive layers 96b, 76, and 86 are bonded above tapered conductive layers 97b, 77, and 87.

Accordingly, the cross section taken along the Z axis of the portion obtained by bonding the conductive layer 76 and the conductive layer 77 has a non-rectangular shape, with its side walls not being linear. In other words, the side surfaces of the conductive layer 77 may not be positioned on an extension of the side surface of the conductive layer 76. Based on such a difference in shape of the side surfaces, it is possible to distinguish such a bonding pad from a general interconnect layer, even if a displacement in position of bonding is not caused. The same applies to the set of the conductive layers 96b and 97b and the set of the conductive layers 86 and 87.

Also, if the conductive layer 76 and the conductive layer 77 are bonded, a bottom surface, a side surface, and an upper surface of the integrated copper forming the conductive layer 76 and the conductive layer 77 are covered with a barrier metal. On the other hand, in a general interconnect layer using copper, an insulating layer (SiN, SiCN, etc.) equipped with an antioxidant function of copper is provided on an upper surface of the copper, and a barrier metal is not provided. Accordingly, it is possible to distinguish such a bonding pad from a general interconnect layer.

### <4> Other Modifications

In the first to second embodiments, the structure of each of the semiconductor memory devices 1 to 1b may have a structure other than those described above. Structures according to the modification of the first embodiment are applicable to the second embodiment. The structures shown in the modification of the first embodiment may be, either in part or in combination, applicable to the first and second embodiments.

Herein, the term “couple” refers to electrical coupling, and does not exclude intervention of another element. Electrical coupling may have an insulator intervening as long as such coupling is capable of operating in a manner similar to electrical coupling without intervention of an insulator.

The first and second embodiments described above have been presented by way of example only, and are not intended to limit the scope of the invention. The first and second embodiments may be embodied in a variety of other forms, and various omissions, substitutions and variations may be made without departing from the spirit of the invention. The first and second embodiments and their modifications are included in the scope and spirit of the invention and are included in the scope of the claimed inventions and their equivalents.

What is claimed is:

1. A semiconductor memory device, comprising:
a substrate including a first region and a second region that surrounds the first region as viewed from above;
a layer stack provided above the substrate in the first region as viewed in a first direction;
a first conductor provided on the substrate in the second region and extending in the first direction;
a second conductor provided on the first conductor and extending in a direction approaching the second region from the first region; and
a third conductor provided on the second conductor and extending in the first direction, an upper surface of the third conductor reaching at least a height of an upper surface of the layer stack, wherein
the third conductor is positioned farther from the first region than the first conductor,
the third conductor is not opposed to the first conductor in the first direction, and
a set of the first conductor, the second conductor, and the third conductor surrounds the first region as viewed from above.

2. The semiconductor memory device according to claim 1, wherein
the set of the first conductor, the second conductor, and the third conductor includes a portion extending in a second direction and a portion extending in a third direction, and thereby surrounds the first region as viewed from above, the second direction intersecting the first direction, and the third direction intersecting the first and second directions.

3. The semiconductor memory device according to claim 1, further comprising:
a fourth conductor extending in the first direction and positioned closer to the first region than the third conductor, wherein
the fourth conductor does not abut on the second conductor and the third conductor, is provided above the second conductor in the first direction, and surrounds the first region as viewed from above.

4. The semiconductor memory device according to claim 1, wherein
the substrate includes a first insulator provided in a region that is below a region between the first conductor and a region below the third conductor and that includes an upper surface of the substrate.

5. The semiconductor memory device according to claim 4, wherein
the first insulator includes a portion extending in a second direction and a portion extending in a third direction, and thereby surrounds the first region as viewed from above, the second direction intersecting the first direction, and the third direction intersecting the first and second directions.

6. The semiconductor memory device according to claim 1, further comprising:
a fifth conductor provided farther from the first region than the first conductor and extending in the first direction, wherein
the fifth conductor does not abut on the second conductor,
the fifth conductor is opposed to the third conductor in the first direction, and
the fifth conductor surrounds the first region as viewed from above.

7. The semiconductor memory device according to claim 1, further comprising:
a first insulating layer provided on the substrate; and
a second insulating layer provided on the first insulating layer, wherein
the third conductor includes a first sub-conductor provided in the first insulating layer and a second sub-conductor provided in the second insulating layer,
an upper surface of the first sub-conductor abuts on a bottom surface of the second sub-conductor,
each of the first sub-conductor and the second sub-conductor contains copper, and
the third conductor includes a portion containing tungsten in each of a region above the second sub-conductor in the first direction and a region below the first sub-conductor in the first direction.

8. The semiconductor memory device according to claim 1, further comprising:
a first conductive layer provided on the layer stack and a pillar penetrating the layer stack in the first direction, wherein
an upper portion of the pillar is included in the first conductive layer, and
the upper surface of the third conductor reaches at least a height of a lower surface of the first conductive layer.

9. The semiconductor memory device according to claim 1, further comprising:
a resin film provided above the layer stack in the first direction, wherein
the resin film is not provided at a position farther from the first region than the third conductor.

10. The semiconductor memory device according to claim 1, wherein
the layer stack includes a plurality of word lines aligned in the first direction, and
a memory cell is formed at an intersection of a pillar penetrating the word lines in the first direction and one of the word lines.

11. The semiconductor memory device according to claim 1, further comprising:
a sixth conductor provided on the substrate in the second region and extending in the first direction;
a seventh conductor provided on the sixth conductor and extending in a direction approaching the first region from the second region; and
an eighth conductor provided on the seventh conductor and extending in the first direction, an upper surface of the eighth conductor reaching at least the height of the upper surface of the layer stack, the eighth conductor being positioned farther from the first region than the third conductor, wherein
the sixth conductor is positioned farther from the first region than the eighth conductor,
the eighth conductor is not opposed to the sixth conductor in the first direction, and
a set of the sixth conductor, the seventh conductor, and the eighth conductor surrounds the first region as viewed from above.

12. The semiconductor memory device according to claim 11, wherein
the eighth conductor is positioned farther from the first region than the third conductor by a first distance,
the third conductor is positioned farther from the first region than the first conductor by a second distance,
the sixth conductor is positioned farther from the first region than the eighth conductor by a third distance, and
the first distance, the second distance, and the third distance are substantially identical in length.

13. The semiconductor memory device according to claim 11, wherein
the set of the first conductor, the second conductor, and the third conductor includes a portion extending in a second direction and a portion extending in a third direction, and thereby surrounds the first region as viewed from above, the second direction intersecting the first direction, and the third direction intersecting the first and second distances, and
the set of the sixth conductor, the seventh conductor, and the eighth conductor includes a portion extending in the second direction and a portion extending in the third direction, and thereby surrounds the first region as viewed from above.

14. The semiconductor memory device according to claim 11, further comprising:
a plurality of fifth conductors extending in the first direction between the first conductor and the sixth conductor, wherein
the fifth conductors do not abut on each other, and do not abut on the first conductor, the second conductor, the sixth conductor, and the seventh conductor,
the fifth conductors are not positioned below a region between the third conductor and the eighth conductor, and
the fifth conductors surround the first region as viewed from above.

15. The semiconductor memory device according to claim 14, wherein
the set of the first conductor, the second conductor, and the third conductor includes a portion extending in a second direction and a portion extending in a third direction, and thereby surrounds the first region as viewed from above, the second direction intersecting the first direction, and the third direction intersecting the first and second directions,
the set of the sixth conductor, the seventh conductor, and the eighth conductor includes a portion extending in the second direction and a portion extending in the third direction, and thereby surrounds the first region as viewed from above, and
each of the fifth conductors includes a portion extending in the second direction and a portion extending in the third direction, and thereby surrounds the first region as viewed from above.

16. The semiconductor memory device according to claim 14, wherein
the first conductor, the sixth conductor, and the fifth conductors are arranged at substantially equal intervals in a second direction intersecting the first direction.

17. The semiconductor memory device according to claim 11, further comprising:
a fourth conductor extending in the first direction and positioned closer to the first region than the third conductor; and
a ninth conductor extending in the first direction and positioned farther from the first region than the eighth conductor, wherein
the fourth conductor does not abut on the second conductor and the third conductor,
the ninth conductor does not abut on the seventh conductor and the eighth conductor,
the fourth conductor is provided above the second conductor in the first direction,
the ninth conductor is provided above the seventh conductor in the first direction,
the fourth conductor surrounds the first region as viewed from above, and
the ninth conductor surrounds the first region as viewed from above.

18. The semiconductor memory device according to claim 11, further comprising:
a second insulator provided on the substrate; and
a tenth conductor partially provided on the second insulator, the tenth conductor not being provided below a region between the third conductor and the eighth conductor.

19. The semiconductor memory device according to claim 11, wherein
the substrate includes a third insulator provided in a region that is below a region between the third conductor and the eighth conductor and that includes an upper surface of the substrate.

20. The semiconductor memory device according to claim 11, further comprising:
a third insulating layer provided above the third conductor and the eighth conductor, wherein
the third insulating layer includes, above a region between the third conductor and the eighth conductor, a trench provided in an upper surface of the third insulating layer.
